(19) United States
(12) Patent Application Publication
(10) Pub. No.: US 2026/0304828 A1
(43) Pub. Date: Oct. 1, 2026

(54) SEMICONDUCTOR DEVICE

(71) Applicant: ROHM Co., LTD., Kyoto (JP)

(72) Inventors: Casey Clendennen, Kyoto (JP); Haruki Goto, Kyoto (JP); Junya Ikeda, Kyoto (JP); Koki Kaburaki, Kyoto (JP)

(21) Appl. No.: 19/572,511

(22) Filed: Mar. 19, 2026

(30) Foreign Application Priority Data
Mar. 26, 2025 (JP) 2025-051742

(51) Int. Cl. H10D 30/66; H10D 8/00; H10D 62/10; H10D 62/60; H10D 64/00; H10D 84/00; H10D 8/01; H10D 30/01; H10D 84/01

(52) U.S. Cl. CPC H10D 30/665; H10D 8/422; H10D 62/107; H10D 62/126; H10D 62/60; H10D 64/111; H10D 84/143; H10D 8/045; H10D 30/0291; H10D 84/0109

(57) ABSTRACT

Provided is a semiconductor device including a first conductive type semiconductor substrate, a cell region, an outer peripheral region, a first conductive type first semiconductor layer, a first pn region, a second conductive type second semiconductor layer, a second pn region, a first conductive type third semiconductor layer, and an insulating layer.

### PRIORITY

The present disclosure contains subject matter related to that disclosed in Japanese Patent Application No. 2025-051742 filed in the Japan Patent Office on March 26, 2025, the entire content of which is hereby incorporated by reference.

### BACKGROUND

The present disclosure relates to a semiconductor device.

Japanese Patent Laid-open No. 2016-111129 describes a semiconductor device using a super junction structure.

### BRIEF DESCRIPTION OF THE DRAWINGS

FIG. 1 is a schematic plan view of an example semiconductor device according to a first embodiment;

FIG. 2 is a schematic plan view of an enlarged part of the semiconductor device depicted in FIG. 1;

FIG. 3 is a schematic plan view of an enlarged part of the semiconductor device depicted in FIG. 1;

FIG. 4 is a schematic plan view of an enlarged part of the semiconductor device depicted in FIG. 1;

FIG. 5 is a schematic cross-sectional view taken along line F5 to F5 in FIG. 4;

FIG. 6 is an enlarged view of a part of FIG. 5;

FIG. 7 is a diagram depicting a relation between a sectional structure of the part in FIG. 5 and an impurity concentration distribution;

FIG. 8 is a schematic cross-sectional view for illustrating a manufacture step of an example semiconductor device according to the first embodiment;

FIG. 9 is a schematic cross-sectional view following the step in FIG. 8;

FIG. 10 is a schematic cross-sectional view following the step in FIG. 9;

FIG. 11 is a schematic cross-sectional view following the step in FIG. 10;

FIG. 12 is a schematic cross-sectional view following the step in FIG. 11;

FIG. 13 is a schematic cross-sectional view following the step in FIG. 12;

FIG. 14 is a schematic cross-sectional view following the step in FIG. 13;

FIG. 15 is a diagram depicting a change in a potential in an X axis direction in FIG. 5 in a case where a width of a fourth column is increased;

FIG. 16 is a diagram depicting a change in a potential in the X axis direction in a case where the width of the fourth column is reduced;

FIG. 17 is a schematic cross-sectional view of an example semiconductor device according to a second embodiment;

FIG. 18 is a schematic cross-sectional view of an example semiconductor device according to a third embodiment;

FIG. 19 is a schematic plan view of an enlarged part of a semiconductor device according to a modification;

FIG. 20 is a schematic cross-sectional view of an example semiconductor device according to a modification;

FIG. 21 is a schematic plan view of an enlarged part of a semiconductor device according to a modification;

FIG. 22 is a schematic cross-sectional view of an example semiconductor device according to a modification;

FIG. 23 is a schematic plan view of an enlarged part of a semiconductor device according to a modification;

FIG. 24 is a schematic cross-sectional view of an example semiconductor device according to a modification;

FIG. 25 is a schematic cross-sectional view of an example semiconductor device according to a modification; and

FIG. 26 is a diagram depicting a relation between a sectional structure of a part of the semiconductor device according to a modification and an impurity concentration distribution.

### DETAILED DESCRIPTION

Hereinafter, some embodiments of a semiconductor device according to the present disclosure will be explained with reference to the drawings. For simplicity and clarity, elements in the drawings are not necessarily drawn to scale. In addition, to facilitate understanding, some hatching lines are omitted in the cross-sectional views. The accompanying drawings merely depict exemplary embodiments of the present disclosure, and should not be considered to limit the present disclosure.

The detailed description given below includes a device, a system, and a method for concretizing example embodiments of the present disclosure. This detailed description is for illustrative purposes only, and not intended to limit embodiments of the present disclosure or application/use of the embodiments.

The terms "first," "second," and "third" used in the present disclosure are used simply for labeling purposes, and are not intended for assigning orders to the targets.

The expression "at least one" as used herein means "one or more" of the desired alternatives. As an example, the expression "at least one" as used herein means "only one option" or "both of two options" if the number of options is two. As another example, the expression "at least one" as used herein means "only one option" or "any combination of two or more options" if the number of options is three or more.

### First Embodiment

### Schematic Entire Configuration of Semiconductor Device

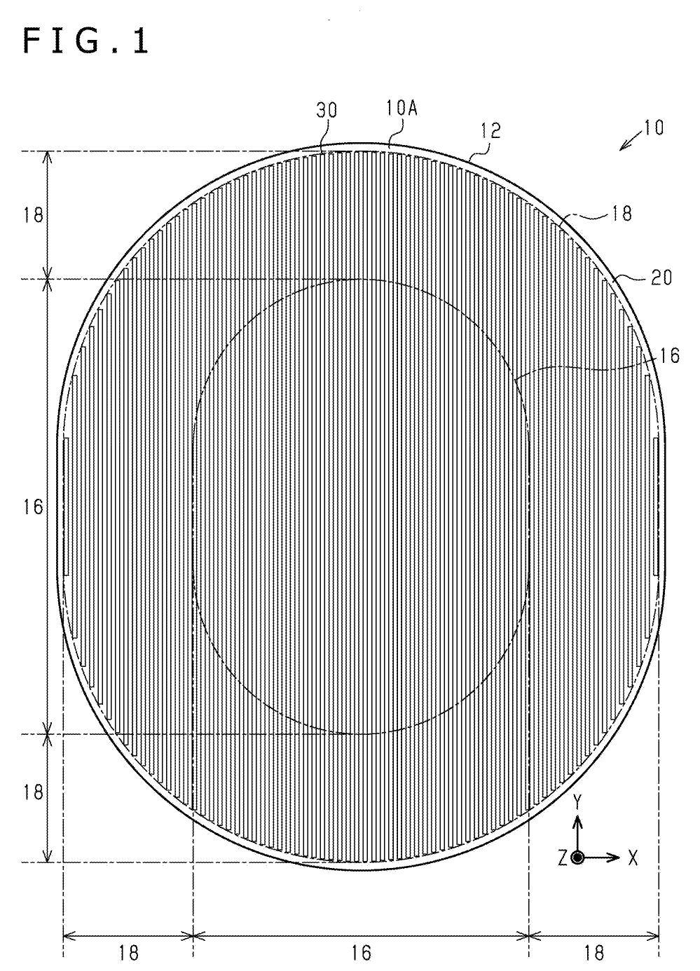

A schematic entire configuration of a semiconductor device 10 according to a first embodiment will be explained with reference to FIGS. 1 to 4. In the first embodiment, the semiconductor device 10 is a metal oxide semiconductor field effect transistor (MOSFET) using a Si semiconductor. It is to be noted that a Z axis direction of XYZ axes which are perpendicular to each other as depicted in FIG. 1 and other drawings is perpendicular to a main surface 10A of the semiconductor device 10. The expression "plan view" as used herein means viewing the semiconductor device 10 from above in the Z axis direction unless otherwise specified. In the present disclosure, the term "above" means both "on" and "above" unless otherwise specified. Specifically, the expression "a first layer formed on a second layer" may mean that the first layer is formed directly on the second layer in one embodiment but does not exclude a structure in which another layer is disposed between the first layer and the second layer in another embodiment.

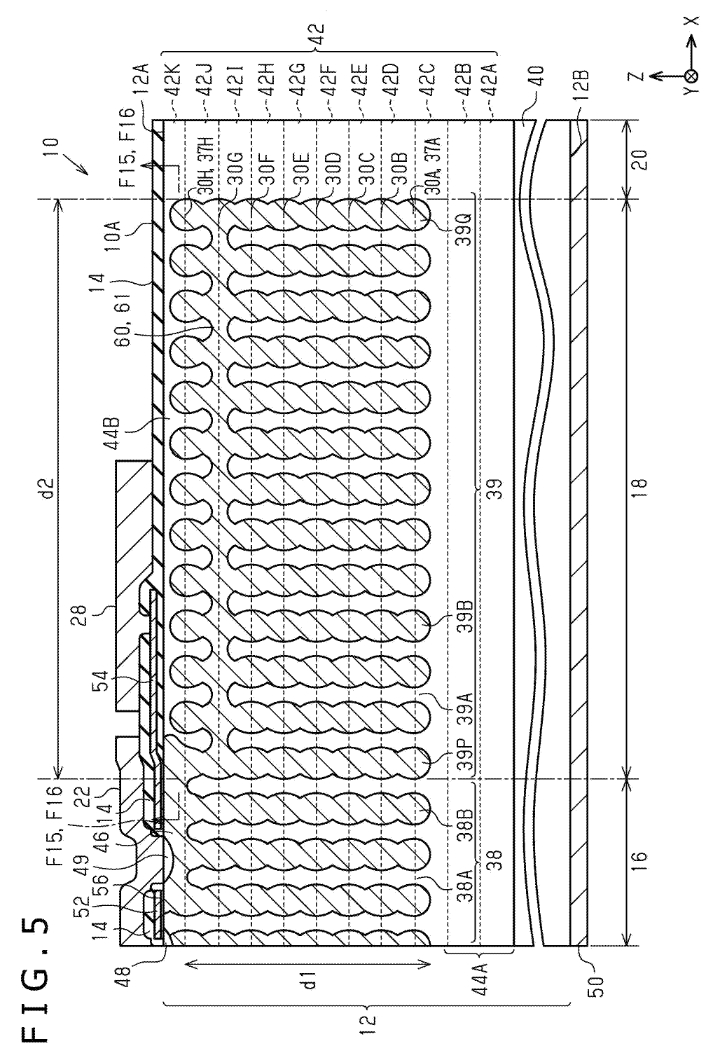

The semiconductor device 10 may have a round-cornered rectangular shape in plan view. The semiconductor device 10 includes a semiconductor layer 12. The semiconductor layer 12 includes an upper surface 12A and a lower surface 12B opposite to the upper surface 12A (see FIG. 5). The semiconductor device 10 includes an insulating layer 14 disposed on the upper surface 12A of the semiconductor layer 12 (see FIG. 5). The semiconductor layer 12 includes a semiconductor substrate 40 (see FIG. 5). The semiconductor substrate 40 includes the lower surface 12B (see FIG. 5). In the following explanation, the upper surface 12A side from the lower surface 12B is defined as "upper side" while the lower surface 12B side from the upper surface 12A is defined as "lower side."

The semiconductor layer 12 is covered with the insulating layer 14, and reference sign 12 indicates an outer edge of the semiconductor layer 12 in FIG. 1. The semiconductor layer 12 may have a round-cornered rectangular shape in plan view. A region defined by the outer edge of the semiconductor layer 12 in FIG. 1 may correspond to one chip (die). The insulating layer 14 may be made of an insulating material such as a silicon oxide film (SiO₂), a silicon nitride film (Si₃N₄), or tetra ethyl ortho silicate (TEOS).

As depicted in FIG. 1, the semiconductor layer 12 includes a cell region 16, an outer peripheral region 18, and an outer peripheral ring region 20. In FIG. 1, a gate pad and a source pad are omitted.

The cell region 16 is a region where a cell is disposed. The cell region 16 is disposed on the semiconductor substrate 40 (see FIG. 5). The cell region 16 is positioned in a region including a center of the semiconductor layer 12 in plan view. The cell region 16 may have a round-cornered rectangular shape in plan view.

The outer peripheral region 18 is a region surrounding the cell region 16 in plan view. The outer peripheral region 18 is disposed on the semiconductor substrate 40 (see FIG. 5). The outer peripheral region 18 may be an annular region of a round-cornered rectangular shape in plan view.

The outer peripheral ring region 20 is a region surrounding the outer peripheral region 18 in plan view. The outer peripheral ring region 20 is a region including a cut surface when the semiconductor device 10 is cut as a single chip. In the outer peripheral ring region 20, a pn junction boundary is not disposed in the semiconductor layer 12. Accordingly, pn junction is not exposed from the cut surface, whereby occurrence of leakage current can be suppressed. The outer peripheral ring region 20 corresponds to an outer side of a seal ring region on an integrated circuit. The outer edge of the outer peripheral ring region 20 coincides with the outer edge of the semiconductor layer 12.

The cell region 16 and the outer peripheral region 18 include a plurality of column regions 30 disposed in the semiconductor layer 12 and having p-type impurities. Each of the column regions 30 is spaced apart from the upper surface 12A of the semiconductor layer 12 (see FIG. 5), and has a fixed depth in the Z axis direction. The column regions 30 extend in a Y axis direction and are spaced apart from each other in an X axis direction. In the present embodiment, the width and pitch of the column regions 30 in the X axis direction are constant in the cell region 16 and the outer peripheral region 18.

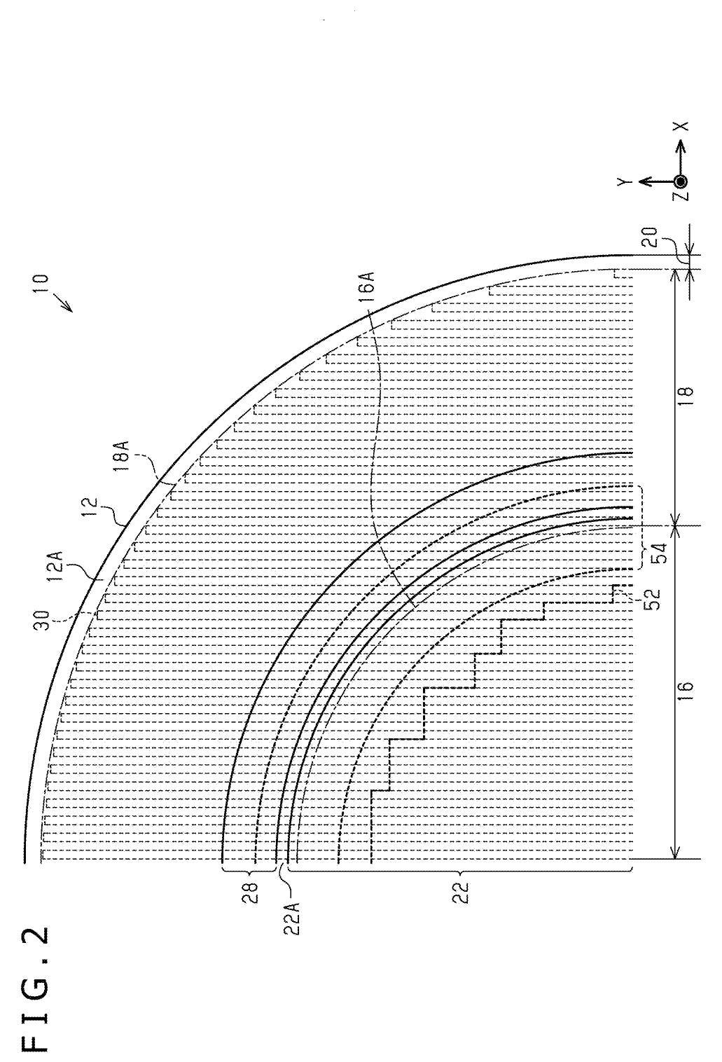

As depicted in FIG. 2, the semiconductor device 10 includes a source wire 22 and a field plate wire 28. Both the source wire 22 and the field plate wire 28 are disposed on the insulating layer 14.

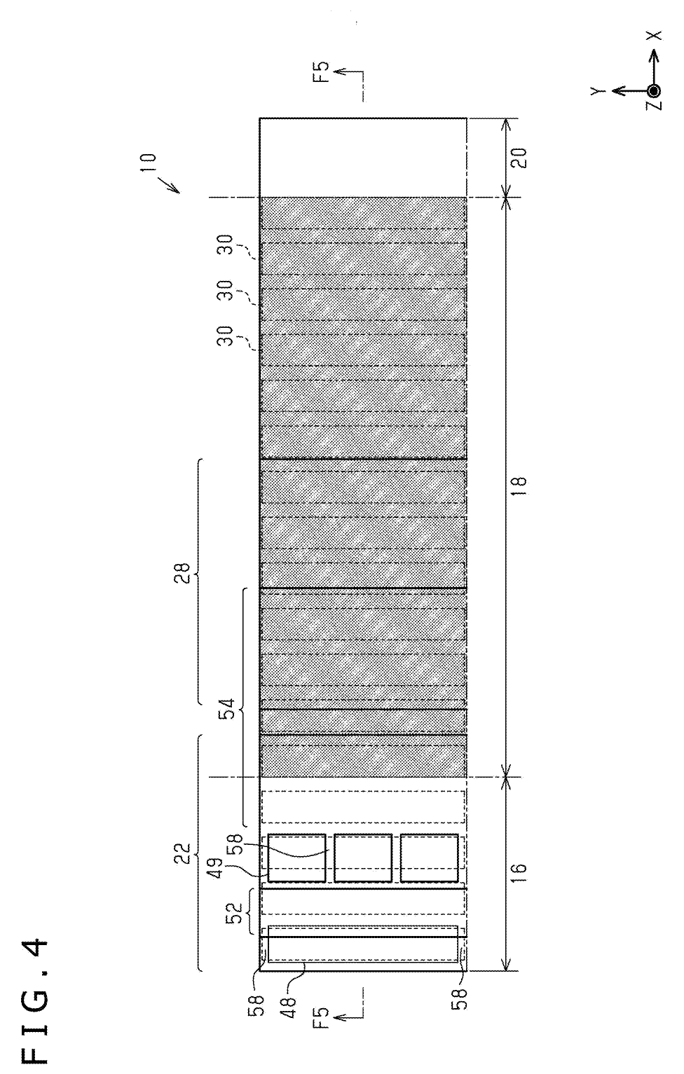

The source wire 22 is disposed so as to cover the cell region 16. In a region of the semiconductor device 10 depicted in FIG. 2, a region where the source wire 22 is disposed has a fan-like shape. In the cell region 16, the source wire 22 is in contact with the semiconductor layer 12 via an opening of the insulating layer 14 (see FIGS. 4 and 5). An outer edge 22A of the source wire 22 is outside an outer edge 16A of the cell region 16 in plan view and is spaced apart from the field plate wire 28.

The field plate wire 28 is disposed closer to the outer edge 16A of the cell region 16 than an outer edge 18A of the outer peripheral region 18. In the region of the semiconductor device 10 depicted in FIG. 2, a region where the field plate wire 28 is disposed is 1/4 of an annular ring shape.

The source wire 22 and the field plate wire 28 may be made of at least one of titanium (Ti), nickel (Ni), gold (Au), silver (Ag), copper (Cu), aluminum (Al), a copper alloy, and an aluminum alloy.

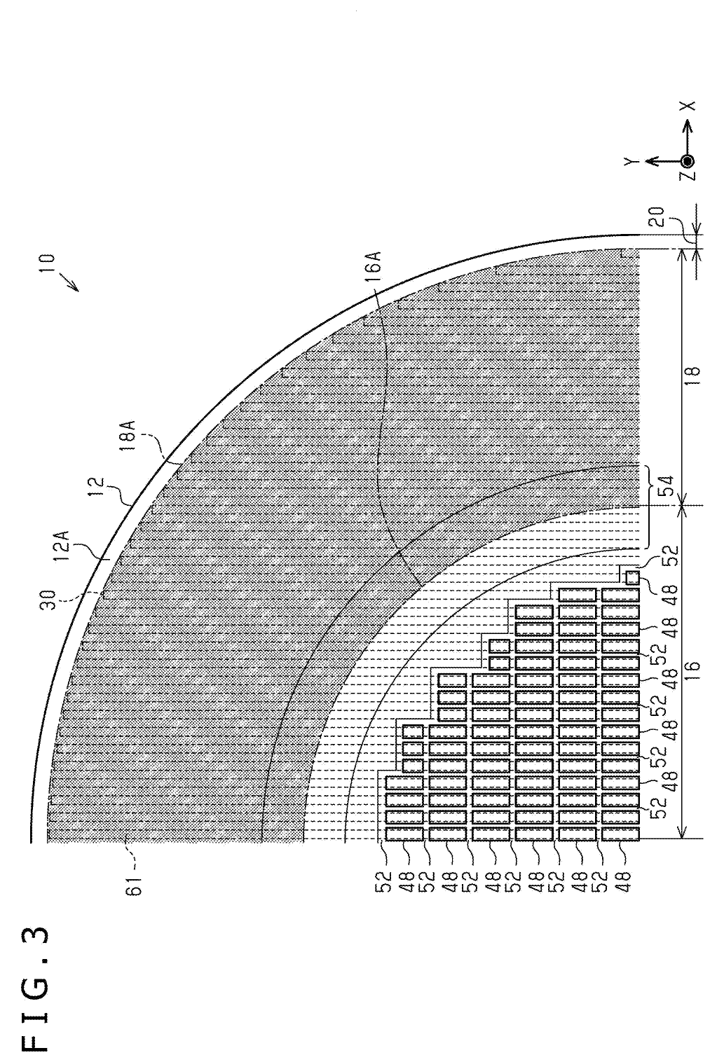

As depicted in FIG. 3, the semiconductor device 10 includes a gate electrode 52, a field plate electrode 54, and a source region 48. In FIG. 3, the insulating layer 14 is omitted and the elements disposed on the upper surface 12A of the semiconductor layer 12 are indicated by solid lines.

The gate electrode 52 is an electrode including a gate of the MOSFET. The gate electrode 52 is disposed in the cell region 16. The gate electrodes 52 are spaced apart from each other in the X axis direction in plan view. The gate electrode 52 extends in the Y axis direction in plan view. As a result, the gate electrodes 52 intersect so as to have a mesh-like shape in the X axis direction and the Y axis direction. The gate electrode 52 has the source region 48 in an opening of the mesh. Portions of the mesh of the gate electrodes 52 extending in the Y axis direction function as gates for controlling electrons flowing out from the source regions 48. Therefore, none of the column regions 30 having p-type impurities is disposed in the Z axis direction of the gate electrodes 52 sandwiched by the source regions 48 in the X axis direction, so that the main current of a transistor including the cell is allowed to flow therethrough. Portions of the mesh of the gate electrodes 52 extending in the X axis direction are used as wires connecting the gate electrodes 52.

The field plate electrode 54 extends from the cell region 16 to the outer peripheral region 18. The field plate electrode 54 is disposed outside the gate electrodes 52. The field plate electrode 54 extends to a position closer to the outer edge 16A of the cell region 16 than the outer edge 18A of the outer peripheral region 18. In the outer peripheral region 18, the field plate electrode 54 is embedded in the insulating layer 14 (see FIG. 5). The field plate electrode 54 is electrically connected to the field plate wire 28 via an opening of the insulating layer 14.

The gate electrodes 52 and the field plate electrode 54 can be formed of polysilicon. The polysilicon includes n-type impurities. Examples of the n-type impurities include phosphorus (P), arsenic (As), and antimony (Sb). The n-type impurity concentration of the polysilicon may be 1.0 × 10¹⁹ to 5.0 × 10²⁰ cm⁻³, for example.

The source region 48 is a region including a source of the MOSFET. The source regions 48 are disposed in openings of the mesh of the gate electrodes 52 which are arranged in the mesh-like shape in the cell region 16. The source regions 48 are exposed from the upper surface 12A of the semiconductor layer 12. The source regions 48 are spaced from each other in the X axis direction and the Y axis direction, and are arranged with a certain pitch. The source region 48 includes n-type impurities. The n-type impurity concentration of the source region 48 may be 1.0 × 10¹⁹ to 5.0 × 10²⁰ cm⁻³, for example.

As depicted in FIG. 4, the semiconductor device 10 includes a plurality of outer peripheral diodes 49 between the field plate electrode 54 and the gate electrode 52 in the cell region 16.

The outer peripheral diode 49 functions as a body diode of the MOSFET. The outer peripheral diodes 49 are arranged between the gate electrode 52 and the field plate electrode 54. The outer peripheral diode 49 includes p-type impurities. Examples of the p-type impurities include boron (B) and indium (In). The concentration of the p-type impurities may be 1.0 × 10¹⁹ to 5.0 × 10²⁰ cm⁻³, for example.

The semiconductor device 10 includes a polysilicon wire 58 disposed between the outer peripheral diodes 49 adjacent to each other in the Y axis direction in plan view. The polysilicon wire 58 connects the gate electrode 52 and the field plate electrode 54 to each other. The polysilicon wire 58 is disposed in the insulating layer 14 disposed between the outer peripheral diodes 49 adjacent to each other in the Y axis direction.

The semiconductor device 10 includes the polysilicon wire 58 disposed between the source regions 48 adjacent to each other in the X axis direction in plan view. The polysilicon wire 58 connects the gate electrodes 52 to each other. The polysilicon wire 58 is disposed in the insulating layer 14 disposed between the source regions 48 adjacent to each other in the Y axis direction.

In a case where the column region 30 is disposed in a position between the outer peripheral diode 49 and the source region 48, the column region 30 has a portion that does not overlap the gate electrode 52 in plan view. When the gate electrode 52 is in an on state, electrons flow from the source region 48 to a channel below the gate electrode 52. Here, an n-type semiconductor layer is exposed in an area functioning as a main current channel directly below the gate electrode 52. In this area where the n-type semiconductor layer is exposed, no column region 30 is disposed.

### SCHEMATIC CROSS-SECTIONAL CONFIGURATION OF SEMICONDUCTOR DEVICE

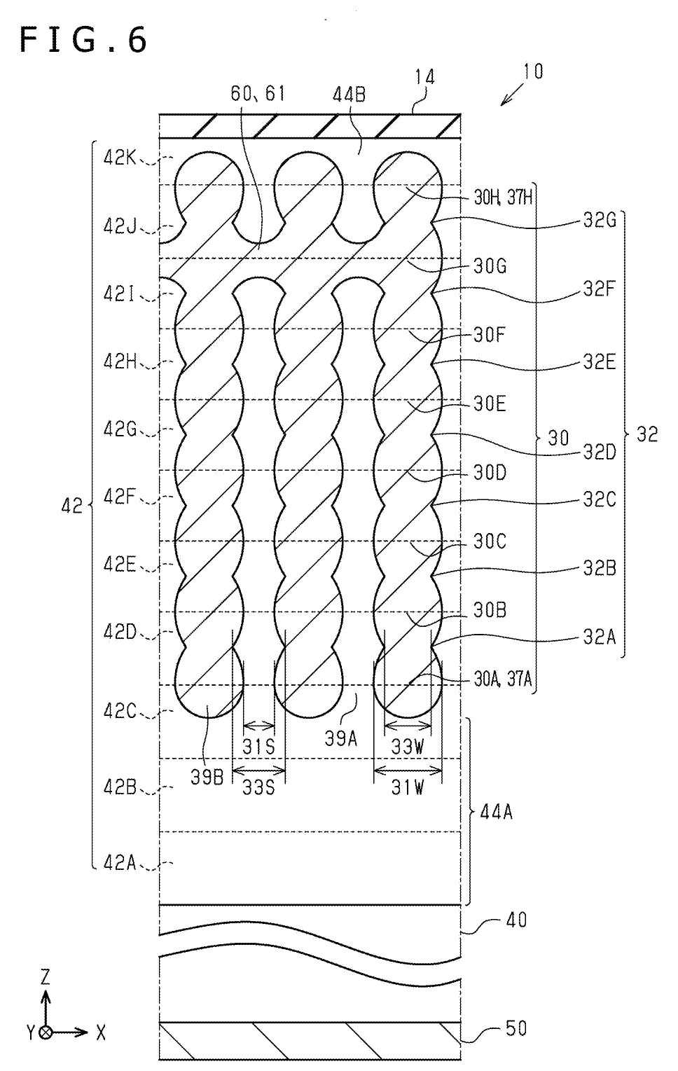

With reference to FIGS. 5 and 6, a cross-sectional configuration of the semiconductor layer 12 will be explained. It is to be noted that the configuration of the semiconductor layer 12 is common in the cell region 16 and the outer peripheral region 18.

As depicted in FIG. 5, the semiconductor layer 12 includes an upper surface 12A and a lower surface 12B opposite to the upper surface 12A. The Z axis direction is perpendicular to the upper surface 12A and the lower surface 12B of the semiconductor layer 12. It can be said that the Z axis direction is a thickness direction of the semiconductor layer 12. The semiconductor layer 12 includes a semiconductor substrate 40 and an epitaxial layer 42 disposed on the semiconductor substrate 40. The semiconductor substrate 40 includes the lower surface 12B of the semiconductor layer 12. The epitaxial layer 42 includes the upper surface 12A of the semiconductor layer 12. In the present embodiment, the semiconductor substrate 40 is an n-type Si substrate. In addition, the epitaxial layer 42 is an n-type Si epitaxial layer. The semiconductor substrate 40 can correspond to a drain region of the MOSFET.

The n-type impurity concentration of the semiconductor substrate 40 may be 1.0 × 10¹⁸ to 5.0 × 10²⁰ cm⁻³, for example. In one example, the n-type impurity concentration of the epitaxial layer 42 may be 1.0 × 10¹⁶ to 7.0 × 10¹⁵ cm⁻³.

In one example, the thickness of the semiconductor substrate 40 is 725 μm. The thickness of the epitaxial layer 42 may be 10 to 100 μm.

In the present embodiment, the epitaxial layers 42 include a plurality of first to eleventh n type epitaxial layers 42A to 42K layered in the Z direction by a multi-epitaxial growth method, as indicated by dotted lines in FIG. 6. Each of the epitaxial layers 42A to 42K is an n-type semiconductor layer formed by epitaxial growth while doping impurities. Eleven epitaxial layers 42A to 42K include the first epitaxial layer 42A, the second epitaxial layer 42B, ..., the eleventh epitaxial layer 42K in this order from the bottom. The thickness of the epitaxial layer 42A to 42K in the Z axis direction is substantially the same. The thickness of each of the epitaxial layer 42A to 42K may be 1 to 10 μm. Alternatively, the thickness and the number of the epitaxial layers 42A to 42K layered in the Z axis direction can freely be set.

As depicted in FIG. 5, the epitaxial layer 42 includes a first semiconductor layer 44A, a first pn region 38 and a second semiconductor layer 46 disposed in the cell region 16, a second pn region 39 and a third semiconductor layer 44B disposed in the outer peripheral region 18, and the outer peripheral ring region 20.

The first semiconductor layer 44A is an n-type semiconductor layer disposed across both the cell region 16 and the outer peripheral region 18 on the semiconductor substrate 40. The first semiconductor layer 44A includes a part of a drift layer of the MOSFET. The first semiconductor layer 44A is formed of the first epitaxial layer 42A and the second epitaxial layer 42B of the epitaxial layers 42, and a second epitaxial layer 42B-side portion of the third epitaxial layer 42C. The upper surface of the first semiconductor layer 44A is in contact with the lower surface of the first pn region 38 and the second pn region 39. The n-type impurity concentration of the first semiconductor layer 44A may be 7 × 10¹⁵ to 1 × 10¹⁶ cm⁻³.

The second semiconductor layer 46 is a p-type semiconductor layer formed by selectively ion-injecting p-type impurities into the n-type epitaxial layer 42. The second semiconductor layer 46 includes a body region of the MOSFET. The second semiconductor layer 46 is positioned above the first pn region 38, extends in the X axis direction, and is connected to the second column 38B. The p-type impurity concentration of the second semiconductor layer 46 may be 1 × 10¹⁶ to 1 × 10²⁰ cm⁻³. The second semiconductor layer 46 may include a region projecting from the cell region 16 toward the outer peripheral region 18.

The source region 48 is an n-type semiconductor layer formed by selectively ion-injecting n-type impurities into the second semiconductor layer 46. In the cell region 16, the source region 48 is disposed adjacent to the gate electrode 52 in the X axis direction. In FIG. 5, the source region 48 is disposed opposite to the outer peripheral diode 49 with respect to the gate electrode 52.

The third semiconductor layer 44B is an n-type semiconductor layer positioned above the second pn region 39, extending in the X axis direction, and connected to the third column 39A. The third semiconductor layer 44B includes a portion of the eleventh epitaxial layer 42K. The third semiconductor layer 44B is exposed from the upper surface 12A of the semiconductor layer 12. The lower surface of the third semiconductor layer 44B is in contact with the upper surface of the second pn region 39. The n-type impurity concentration of the third semiconductor layer 44B may be 7 × 10¹⁵ to 1 × 10¹⁶ cm⁻³. The third semiconductor layer 44B may include a region that is eroded from the cell region 16 toward the outer peripheral region 18 by the second semiconductor layer 46.

The insulating layer 14 is disposed on the second semiconductor layer 46 and the third semiconductor layer 44B.

Via the insulating layer 14, the source wire 22 is spaced apart from the gate electrode 52 and the field plate electrode 54. The source wire 22 is disposed on the insulating layer 14 and on the outer peripheral diode 49.

The field plate electrode 54 is embedded in the insulating layer 14 in the outer peripheral region 18, and is electrically connected to the field plate wire 28 via the opening of the insulating layer 14.

The outer peripheral diode 49 functions as a body contact region of the MOSFET. The outer peripheral diode 49 is disposed on the second semiconductor layer 46. In addition, the outer peripheral diode 49 includes a p-type region-side portion of a pn junction between the second semiconductor layer 46 which is a p-type semiconductor layer and the epitaxial layer 42 which is an n-type semiconductor layer. The outer peripheral diode 49 has a p-type impurity concentration that is higher than the p-type impurity concentration of the second semiconductor layer 46. The p-type impurity concentration of the outer peripheral diode 49 may be 1 × 10¹⁷ to 1 × 10²¹ cm⁻³.

The outer peripheral ring region 20 is an n-type semiconductor layer disposed outside the outer peripheral region 18 on the semiconductor substrate 40. The outer peripheral ring region 20 includes a portion of a drain of the MOSFET. The outer peripheral ring region 20 is formed of the first to eleventh epitaxial layers 42A to 42K of the epitaxial layers 42. The upper surface of the outer peripheral ring region 20 coincides with the upper surface 12A of the semiconductor layer 12. The n-type impurity concentration of the outer peripheral ring region 20 may be 7 × 10¹⁵ to 1 × 10¹⁶ cm⁻³.

The semiconductor device 10 includes a drain electrode 50 disposed on the lower surface 12B of the semiconductor layer 12. The drain electrode 50 is an electrode including a drain of the MOSFET. The drain electrode 50 is electrically connected to the semiconductor substrate 40 which is an n-type semiconductor layer including a portion of the lower surface 12B of the semiconductor layer 12. The drain electrode 50 may include at least one of titanium (Ti), nickel (Ni), gold (Au), silver (Ag), copper (Cu), aluminum (Al), a copper alloy, and an aluminum alloy.

The first pn region 38 is disposed in the cell region 16 in the epitaxial layers 42. The first pn region 38 includes a first column 38A and a second column 38B. The first column 38A is formed of an n-type semiconductor layer. The second column 38B is formed of a p-type semiconductor layer. The first column 38A and the second column 38B are alternately arranged in the X axis direction. A plurality of first columns 38A and a plurality of second columns 38B are disposed. The plurality of first columns 38A and the plurality of second columns 38B are alternately arranged in the X axis direction. The plurality of first columns 38A and the plurality of second columns 38B are disposed so as to extend in the Z axis direction from a bottom of the second semiconductor layer 46 toward the first semiconductor layer 44A. The plurality of second columns 38B and the second semiconductor layer 46 have the same p-type impurities. The plurality of second columns 38B are electrically connected to the second semiconductor layer 46.

The second pn region 39 is disposed in the outer peripheral region 18 in the epitaxial layers 42. The second pn region 39 includes a third column 39A and a fourth column 39B. The third column 39A is formed of an n-type semiconductor layer. The fourth column 39B is formed of a p-type semiconductor layer. The third column 39A and the fourth column 39B are arranged alternately in the X axis direction. A plurality of third columns 39A and a plurality of fourth columns 39B are disposed. The plurality of third columns 39A and the plurality of fourth columns 39B are disposed so as to extend in the Z axis direction from a bottom of the third semiconductor layer 44B toward the first semiconductor layer 44A. The third semiconductor layer 44B, the plurality of third columns 39A, and the first semiconductor layer 44A have the same n-type impurities.

The first pn region 38 and the second pn region 39 are disposed in such a way that a lower end of the first pn region 38 and a lower end of the second pn region 39 overlap when viewed from a direction perpendicular to the Z axis direction. In the present embodiment, in the Z axis direction, the lower surface position of the first pn region 38 is the same as the lower surface position of the second pn region 39. Alternatively, the lower surface position of the first pn region 38 and the lower surface position of the second pn region 39 may be different from each other in the Z axis direction. In addition, the arrangement directions of the first pn region 38 and the second pn region 39 are not limited to the X axis direction. The X axis direction and the Y axis direction may be combined, or the arrangement direction of the first pn region 38 may be different from the arrangement direction of the second pn region 39.

In the drawings accompanying the present description, an outer edge of each column region 30 represents a pn boundary. That is, the boundary where the p-type impurity concentration and the n-type impurity concentration are equal to each other is indicated by a solid line, and is noted so as to surround each column region 30. For example, the width of a column means a width that is based on the pn boundary.

The second column 38B and the fourth column 39B are p-type semiconductor regions formed by ion-injecting p-type impurities into the n-type epitaxial layer 42.

In a cross-sectional view from the Y axis direction, the first column 38A disposed between the second columns 38B and the third columns 39A disposed between the fourth columns 39B are n-type semiconductor regions where p-type impurities are not ion-injected. That is, the n-type epitaxial layer 42 in an area where p-type impurities are not ion-injected can be used as they are in the first column 38A and the third column 39A.

Alternatively, the n-type epitaxial layer 42 may be formed by ion-injection of n-type impurities in the first column 38A and the third column 39A. In this case, the n-type impurity concentration of each of the first column 38A and the third column 39A may be higher than the n-type impurity concentration of the epitaxial layer 42. The n-type impurity concentration of the first column 38A and the n-type impurity concentration of the second column 38B may be equal to each other or may be different from each other. Trenches may be formed in the positions of the second column 38B and the fourth column 39B, and semiconductors having p-type impurities may be epitaxially grown to be embedded in the trenches.

A plurality of the second columns 38B and the fourth columns 39B are arranged to be spaced from each other in the X axis direction. The second column 38B and the fourth column 39B are disposed so as to extend along the Y axis direction. A plurality of the first columns 38A and the third columns 39A are arranged to be spaced from each other in the X axis direction. The first columns 38A and the third columns 39A are disposed so as to extend along the Y axis direction.

Therefore, in the first pn region 38 and the second pn region 39, n-type regions and p-type regions are disposed in stripe shapes in plan view. In other words, in the first pn region 38 and the second pn region 39, n-type and p-type planar semiconductor layers extending on the YZ plane are alternately arranged.

Accordingly, the first pn region 38 and the second pn region 39 form a super junction structure. The super junction structure is formed by alternately arranging the p-type columns 38B and 39B and the n-type columns 38A and 39A.

In the present embodiment, the X axis direction width of the first pn region 38 and the X axis direction width of the second pn region 39 are equal to each other. In addition, the pitch of the first pn region 38 in the X axis direction is equal to the pitch of the second pn region 39 in the X axis direction. Alternatively, the pitch and width in the X axis direction may vary in the first pn region 38 and the second pn region 39.

In the first pn region 38, the first column 38A is disposed so as to extend in the Z axis direction from directly below the gate electrode 52. In addition, in the first pn region 38, the second column 38B is disposed so as to extend in the Z axis direction from directly below the second semiconductor layer 46.

The semiconductor device 10 includes a gate insulating film 56 disposed between the second semiconductor layer 46 and the gate electrode 52. When the gate electrode 52 is turned on, a channel is formed on a surface of the second semiconductor layer 46, and the channel is connected to the source region 48 which is next to the gate electrode 52. Electrons flowing from the source region 48 move in the Z axis direction via the first column 38A which is exposed directly below the gate electrode 52, passes through the first semiconductor layer 44A, and reaches the drain electrode 50. The gate insulating film 56 may be formed of a silicon oxide film, a silicon nitride film, a silicon oxynitride film, a hafnium oxide film, an alumina film, or a tantalum oxide film, for example. The gate insulating film 56 may have a thickness of 30 to 70 nm, for example.

The semiconductor device 10 includes a body region formed of the source region 48, the gate electrode 52, the gate insulating film 56, and the second semiconductor layer 46, a drift region formed of the first semiconductor layer 44A and the first columns 38A, and the drain electrode 50 to include an n-type MOSFET. The main current passes through the drain electrode 50, the first semiconductor layer 44A of the semiconductor layer 12, the first columns 38A, the upper surface 12A located directly below the gate electrode 52, and the channel on the second semiconductor layer 46 located below the gate electrode 52 in this order, and then, flows into the source region 48. It is to be noted that the present embodiment forms the n-type MOSFET but a p-type MOSFET may be formed instead. Further, a trench MOS or other types of MOS may be adopted in place of the planar type MOSFET.

### CONFIGURATION OF FIELD PLATE

In an off state of the transistor, when a power supply voltage Vdd is applied to the drain electrode 50, the power supply voltage Vdd is applied to the third semiconductor layer 44B, the outer peripheral ring region 20, and the first semiconductor layer 44A. In an off state of the transistor, a gate potential is given to the field plate wire 28 and the field plate electrode 54. Accordingly, via the insulating layer 14, a potential difference corresponding to a power supply-gate voltage is generated between the field plate wire 28 and the field plate electrode 54 and the third semiconductor layer 44B. Thus, a depletion layer expands in the third semiconductor layer 44B. In this manner, the field plate is formed.

In the present embodiment, a gate potential is applied to the field plate electrode 54 and the field plate wire 28, as depicted in FIG. 5, but this is not a limited configuration. In the outer peripheral region 18, the field plate electrode 54 electrically connected to the source wire 22 may be disposed in the insulating layer 14, and potentials of the field plate electrode 54 and the field plate wire 28 may serve as source potentials, which are not depicted though. Even with this configuration, in the off state of the transistor, a potential difference corresponding to the power supply-source voltage is generated between the field plate wire 28 and the field plate electrode 54 and the third semiconductor layer 44B via the insulating layer 14. Thus, a depletion layer expands in the third semiconductor layer 44B.

### SCHEMATIC CROSS-SECTIONAL CONFIGURATION OF COLUMN REGION

As depicted in FIGS. 5 and 6, the fourth column 39B extends from the inside of the third epitaxial layer 42C which is the third layer to the eleventh epitaxial layer 42K which is the 11th layer.

The fourth column 39B has a layered structure in which a plurality of p-type semiconductor regions are layered along the Z axis direction. The plurality of p-type semiconductor regions are connected to each other in the Z axis direction. Accordingly, the plurality of p-type semiconductor regions in the Z axis direction entirely include one of the fourth columns 39B. The plurality of p-type semiconductor regions are formed by multi-epitaxial growth in which ion-injection of p-type impurities and epitaxial growth of a semiconductor are alternately performed.

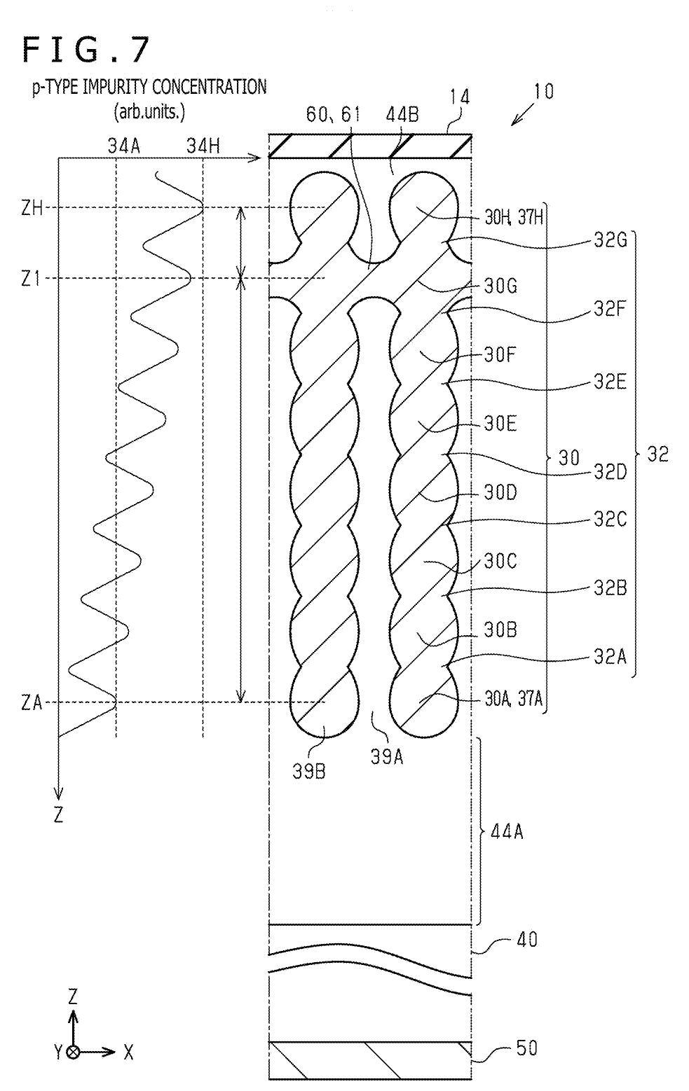

The fourth column 39B is formed of a plurality of regions 30 in the Z axis direction, as depicted in FIGS. 6 and 7. In the present embodiment, the fourth column 39B includes first to eighth regions 30A to 30H. The fourth column 39B includes ends in the Z axis direction. The end of the fourth column 39B including the first region 30A is a fourth lower end 37A. The end of the fourth column 39B including the eighth region 30H is a fourth upper end 37H. A connection portion 32 connecting the first to eighth regions 30A to 30H includes first to seventh connection portions 32A to 32G. Alternatively, the number of the plurality of regions and the number of the connections can freely be set.

In the fourth column 39B, the plurality of regions 30 have different impurity concentrations. The p-type impurity concentrations in the plurality of regions 30 decrease from the fourth upper end 37H toward the fourth lower end 37A. The plurality of regions 30 have different impurity concentrations in the Z axis direction. That is, the plurality of regions 30 having different p-type impurity concentrations in the Z axis direction include the fourth column 39B. The fourth upper end 37H is a region, among the plurality of regions 30, closest to the third semiconductor layer 44B.

Accordingly, a state rich in p-type impurities (p rich) can be achieved on the upper surface side of the second pn region 39, and a state poor in p-type impurities (n rich) can be achieved on the lower surface side. It is to be noted that the decrease of the p-type impurity concentration from the fourth upper end 37H toward the fourth lower end 37A may be a monotonous decrease, a step-functional decrease, or an exponentially functional decrease, and any decrease can be selected.

In the p-type impurity concentration distribution in the first to eighth regions 30A to 30H when viewed in the Z axis direction, a maximum value which represents the peak concentration of the p-type impurity concentration is included in each of the plurality of regions 30, as depicted in FIG. 7. In the present embodiment, each of the regions includes one maximum value. Alternatively, a plurality of maximum values may be included in each of the regions. In addition, the first to eighth regions 30A to 30H include respective minimum values of the p-type impurity concentration in the first to seventh connection portions 32A to 32G. In the present embodiment, each of the region connection portions includes one minimum value.

The X axis direction width of the fourth column 39B has a correlation with the p-type impurity concentration of the fourth column 39B in the Z axis direction, as depicted in FIGS. 6 and 7. The X axis direction width of the fourth column 39B becomes maximum at a position where the p-type impurity concentration in the Z axis direction is at a peak concentration. The X axis direction size of the p-type impurity region at a position where the X axis direction width of the fourth column 39B becomes maximum is defined as a column width 31W. In addition, a spacing between the p-type impurity regions in the X axis direction at the position where the X axis direction width of the fourth column 39B is maximum is defined as a column spacing 31S. The X axis direction width of the fourth column 39B becomes minimum at a position where the p-type impurity concentration in the Z axis direction is at a minimum value. The X axis direction size of the p-type impurity region at the position where the X axis direction width of the fourth column 39B is minimum is defined as a connection portion width 33W. In addition, an X axis direction spacing between the p-type impurity regions at the position where the X axis direction width of the fourth column 39B is minimum is defined as a connection portion spacing 33S. Here, it can be said that the column width 31W is larger than the connection portion width 33W and the column spacing 31S is smaller than the connection portion spacing 33S.

As depicted in FIG. 7, the peak concentrations of the plurality of regions 30 decrease from the fourth upper end 37H toward the fourth lower end 37A.

The fourth column 39B may have a second conductive type impurity concentration distribution including a plurality of peak concentrations in the Z axis direction. The plurality of peak concentrations may include an upper end peak concentration 34H included in the fourth upper end 37H and a lower end peak concentration 34A included in the fourth lower end 37A. The upper end peak concentration 34H may be higher than the lower end peak concentration 34A.

The decrease of the p-type impurity peak concentration from the fourth upper end 37H toward the fourth lower end 37A may be a monotonous decrease, a step-functional decrease, or an exponentially functional decrease, and any decrease can be selected. In addition, variation in the average concentrations of the regions 30 may differ from variation in the peak concentrations thereof. For example, it is possible to make a design in which the peak concentration of a region 30 is high while the average concentration of the region 30 is low.

### CONNECTION STRUCTURE OF FOURTH COLUMN

As depicted in FIG. 5, the plurality of the fourth columns 39B have first to eighth regions 30A to 30H arranged in the Z axis direction. The plurality of the fourth columns 39B have, as both ends in the Z axis direction, fourth upper ends 37H and fourth lower ends 37A. The plurality of the fourth columns 39B include an innermost peripheral fourth column 39P disposed on the cell region 16 side of the outer peripheral region 18 and an outermost peripheral fourth column 39Q disposed adjacent to the outer edge 18A of the outer peripheral region 18, in plan view.

As depicted in FIGS. 5 and 6, the semiconductor device 10 includes, in the fourth columns 39B in the outer peripheral region 18, a connection layer 60 connecting the fourth columns 39B in an area excluding the fourth upper end 37H. The connection layer 60 is a p-type semiconductor layer. The connection layer 60 includes a first connection layer 61. As depicted in FIG. 3, the first connection layer 61 is 1/4 of an annular region of a rounded rectangular region surrounding the outer edge 16A of the cell region 16 and including the outer edge 18A of the outer peripheral region 18 in plan view. The first connection layer 61 connects a plurality of the fourth columns 39B. In the present embodiment, the first connection layer 61 establishes connection from the innermost peripheral fourth column 39P to the outermost peripheral fourth column 39Q. The first connection layer 61 does not connect the sixth regions 30F to each other.

In the plurality of second columns 38B, the second semiconductor layer 46 is directly, electrically connected to the plurality of second columns 38B.

The plurality of the fourth columns 39B are electrically connected to the second semiconductor layer 46 via the first connection layer 61.

In the present embodiment, the first connection layer 61 is disposed in the seventh regions 30G. The p-type impurity concentration of the first connection layer 61 is equal to the p-type impurity concentration of the seventh regions 30G. Alternatively, depending on the number of regions and connections of the fourth column 39B, the first connection layer 61 for connecting any regions to each other may be disposed. In this case, when a lower end peak concentration position in the Z axis direction is ZA, an upper end peak concentration position in the Z axis direction is ZH, the position of the first connection layer 61 in the Z axis direction is Z1 as depicted in FIG. 7, it is desirable that (ZA to Z1) : (Z1 to ZH) ranges from 11:3 to 13:1.

The first connection layer 61 may be disposed between the fourth lower end 37A and the fourth upper end 37H, and may connect portions of the plurality of the fourth columns 39B at the same thickness position. The same thickness position means the same coordinate on the Z axis when viewed in the Z axis direction which is the thickness direction. That is, connecting the portions at the same thickness position is connecting the portions of the plurality of the fourth columns 39B on the same Z axis direction coordinates of the respective fourth columns 39B. A surface formed by connecting the portions of the plurality of the fourth columns 39B on the same Z axis direction coordinates is a surface perpendicular to the Z axis direction. It can be said that the surface formed by connecting the portions of the plurality of the fourth columns 39B on the same Z axis direction coordinates is on an XY plane. The first connection layer 61 extends in a direction parallel with the upper surface 12A of the semiconductor layer 12, and connects the adjacent fourth columns 39B to each other. The first connection layer 61 expands on the XY plane in the outer peripheral region 18 and covers the entire second pn region 39.

The first connection layer 61 may be disposed closer to the fourth upper end 37H than the fourth lower end 37A.

The first connection layer 61 may be disposed in the same thickness position as the seventh region 30G one level lower than the fourth upper end 37H in the Z axis direction and may connect the corresponding regions of the fourth columns 39B.

### MANUFACTURING METHOD FOR FOURTH COLUMN

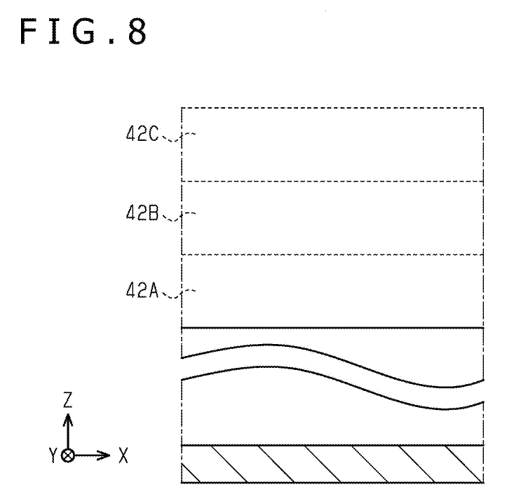

A manufacturing method for the fourth column 39B including a connection layer by multi-epitaxial growth in which ion-injection of p-type impurities and epitaxial growth of a semiconductor are alternately performed, will be explained with reference to FIGS. 8 to 14.

As depicted in FIG. 8, in a first step, a third epitaxial layer 42C is grown on a second epitaxial layer 42B. The film thickness of each epitaxial layer 42A to 42K is 5 μm, for example.

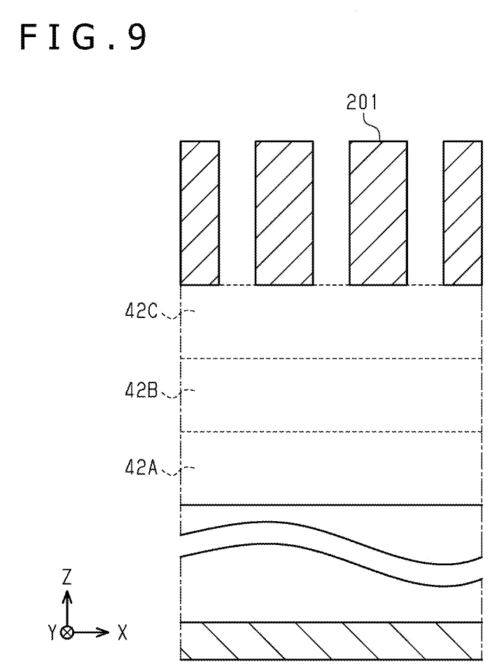

As depicted in FIG. 9, in a second step, a first width resist 201 having an opening where the fourth column 39B is disposed is disposed.

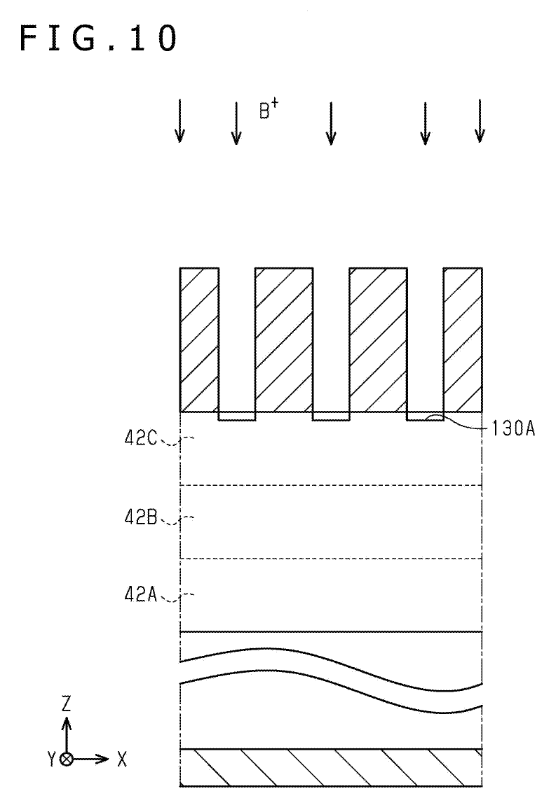

As depicted in FIG. 10, in a third step, p-type impurities are ion-injected with the first width resist 201 serving as a mask. Accordingly, a first ion injection region 130A is disposed on a surface of the third epitaxial layer 42C. The target dose value of the p-type impurities may be 6 × 10¹² to 9 × 10¹² cm⁻² under several KeV to several hundreds KeV. That is, in terms of the p-type impurity concentration, the target value may be 1 × 10¹⁶ to 2 × 10¹⁶ cm⁻³.

The first to third steps are repeated for the fourth epitaxial layer 42D to the eighth epitaxial layer 42H.

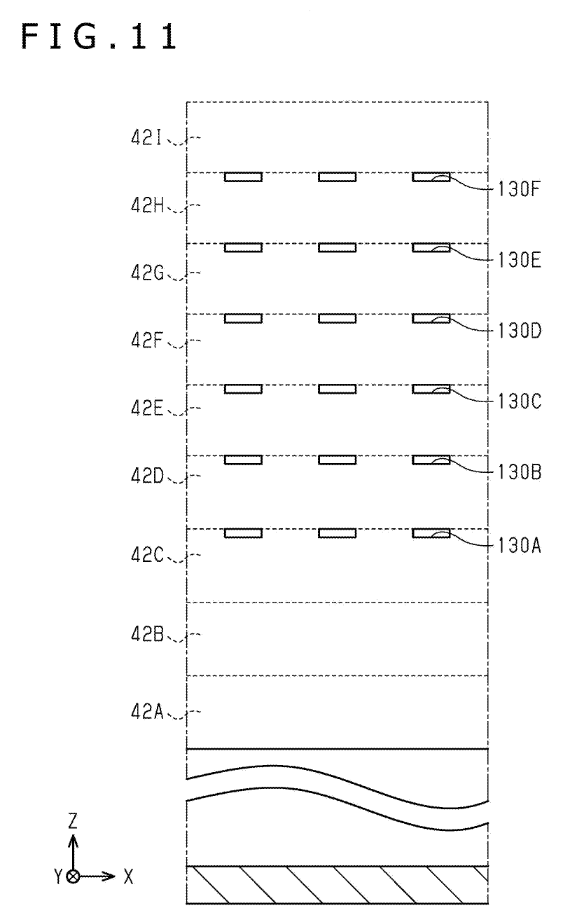

As depicted in FIG. 11, in a fourth step, a ninth epitaxial layer 42I is grown on the eighth epitaxial layer 42H.

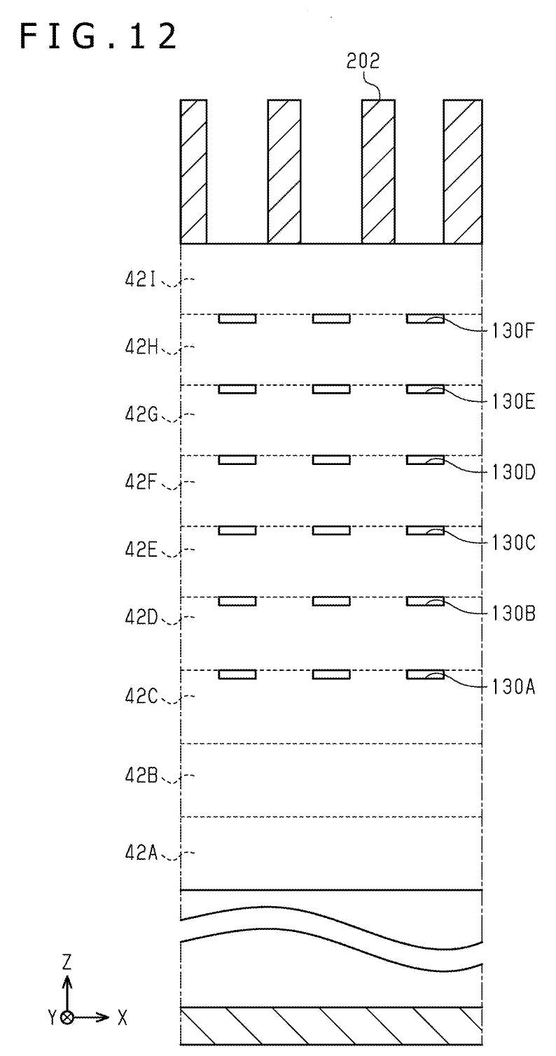

As depicted in FIG. 12, in a fifth step, a second width resist 202 having an opening at a position where the fourth column 39B is disposed is disposed. The opening width of the second width resist 202 is larger than the opening width of the first width resist 201. Through adjustment of this width, a connection with an adjacent region when the impurities are diffused can be made to form a connection layer.

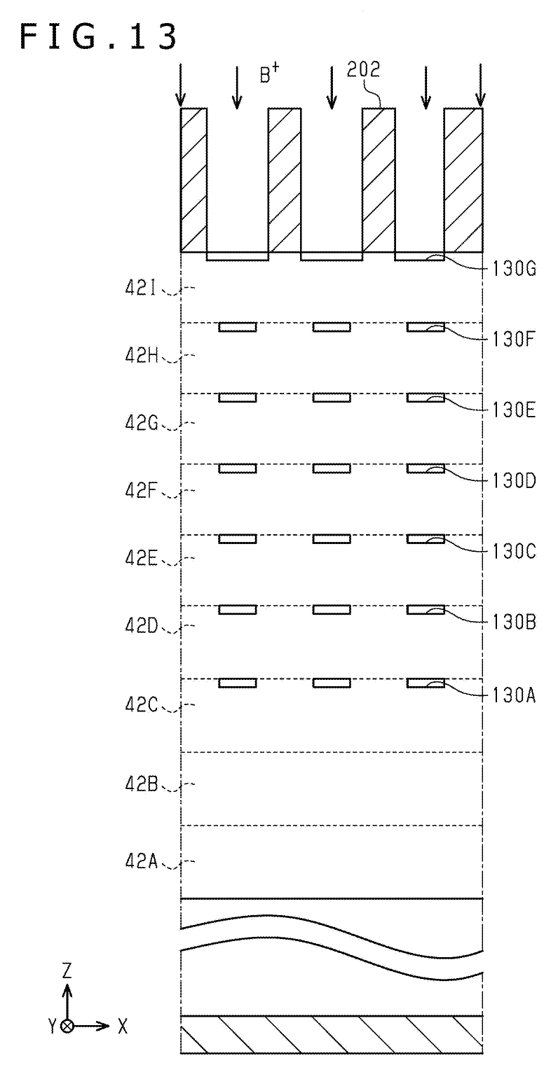

As depicted in FIG. 13, in a sixth step, p-type impurities are ion-injected with the second width resist 202 serving as a mask. Accordingly, a seventh ion injection region 130G is disposed on a surface of the ninth epitaxial layer 42I.

In a seventh step, a tenth epitaxial layer 42J is grown on the epitaxial layer 42I.

In an eighth step, the first width resist 201 having an opening at a position where the fourth column 39B is disposed is disposed.

In a ninth step, p-type impurities are ion-injected with the first width resist 201 serving as a mask. Accordingly, an eighth ion injection region 130H is disposed on a surface of the tenth epitaxial layer 42J.

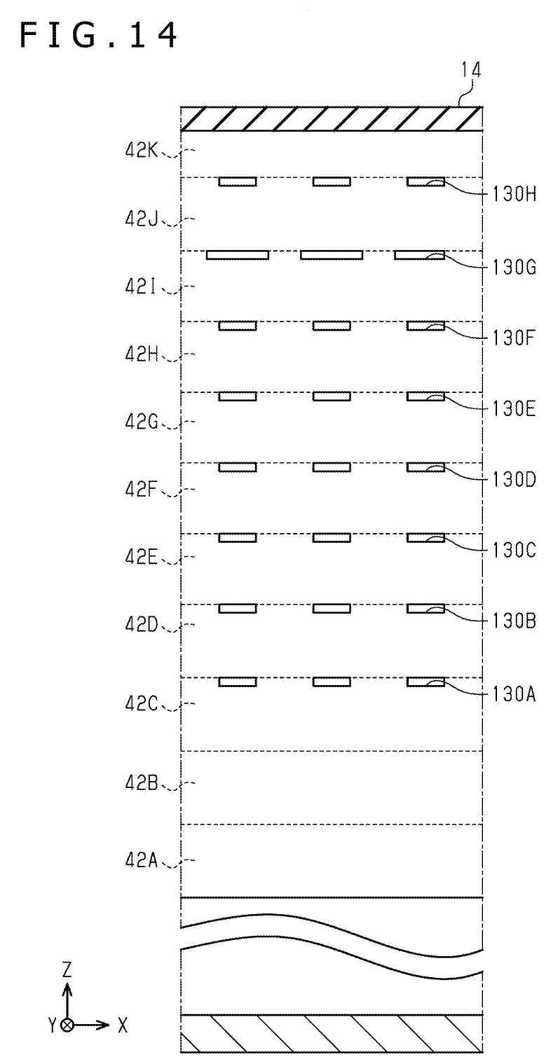

As depicted in FIG. 14, in a tenth step, an eleventh epitaxial layer 42K is grown on the tenth epitaxial layer 42J, and the insulating layer 14 is disposed on a surface thereof.

In an eleventh step, the ion-injected p-type impurities are thermally diffused and activated by annealing. Accordingly, the first to eighth ion injection regions 130A to 130H having been injected in the third to eleventh epitaxial layers 42C to 42K are diffused, so that p-type impurity regions distributed in respective ellipsoidal shapes are connected in the Z axis direction. Thus, the first to eighth regions 30A to 30H are formed. In the first connection layer 61, when the injection width of the p-type impurities is large, the p-type impurities diffuse in the X axis direction and the Y axis direction, so that the adjacent fourth columns 39B are connected. In this manner, the first connection layer 61 is formed. FIG. 6 depicts the finished form.

### OPERATION IN FIRST EMBODIMENT

Operation in the first embodiment will be explained using FIGS. 5, 7, 15, and 16.

As depicted in FIG. 5, the semiconductor device 10 of the present embodiment is a MOSFET. When the MOSFET is an off state, the source region 48, the second semiconductor layer 46, and the gate electrode 52 are grounded while the power supply voltage Vdd is applied to the drain electrode 50. The power supply voltage Vdd is used within a range equal to or lower than the withstand voltage of the semiconductor device 10. Improvement in the withstand voltage of the semiconductor device 10 has been required in such a way that a larger power supply voltage Vdd can be used.

In order to improve the withstand voltage, it is necessary to suppress occurrence of avalanche breakdown in response to application of the power supply voltage Vdd. Therefore, it is necessary to make a design to dispersively distribute electric fields generated in the semiconductor device 10 while preventing local concentrated distribution in an off state.

One of design methods therefor is a super junction structure. In a super junction structure, p-type column regions and n-type column regions are alternately arranged and a pn region is entirely depleted.

Electric field relaxation using a super junction structure requires simultaneously achieving electric field relaxation in the cell region 16 and electric field relaxation in the outer peripheral region 18. Hereinafter, the potential of electrons which are a carrier in the n-type MOSFET is referred to as potential. The inclination of the potential indicates an electric field.

In the cell region 16, since the source region 48 and the second semiconductor layer 46 are disposed on the upper surface 12A of the semiconductor layer 12, the first semiconductor layer 44A to serve as a drain is in contact with the lower surface of the first pn region 38. That is, when viewed in the Z axis direction, a ground potential is given to the third semiconductor layer 44B in a direction from the third semiconductor layer 44B toward the first semiconductor layer 44A, and the potential of the power supply voltage Vdd is given to the first semiconductor layer 44A. That is, in the cell region 16, the potential difference of the power supply voltage Vdd is applied in the Z axis direction in an off state.

The first pn region 38 in the cell region 16 is disposed in order to absorb the potential difference. The n-type impurity concentration of the first column 38A and the p-type impurity concentration of the second column 38B in the first pn region 38 are designed so as to deplete the entire first pn region 38 in an off state. Here, with respect to a direction from the second semiconductor layer 46 toward the first semiconductor layer 44A, the inclination of the potential is fixed. Therefore, when the Z axis direction size of the first pn region 38 is d1, the electric field intensity is Vdd/d1 [V/cm]. It is desirable that at least this electric field is equal to or lower than the avalanche breakdown electric field (e.g., 3 × 10⁵ V/cm for Si) of the semiconductor.

On the other hand, in the outer peripheral region 18, in the boundary between the cell region 16 and the outer peripheral region 18 and a surrounding region thereof, the second semiconductor layer 46 to serve as a ground potential is disposed on the upper surface 12A of the semiconductor layer 12. In the outer peripheral region 18, the third semiconductor layer 44B on the upper surface 12A of the semiconductor layer 12, the outer peripheral ring region 20 outside the outer edge 18A of the outer peripheral region 18, the first semiconductor layer 44A on the lower surface of the second pn region 39 are arranged so as to respectively serve as potentials and surround the second pn region 39. That is, when viewed in the Z axis direction, in a direction from the second semiconductor layer 46 toward the first semiconductor layer 44A, a ground potential is given to the second semiconductor layer 46, and the potential of the power supply voltage Vdd is given to the first semiconductor layer 44A. When viewed in the X axis direction, in a direction from the second semiconductor layer 46 toward the outer peripheral ring region 20, a ground potential is given to the third semiconductor layer 44B, and the potential of the power supply voltage Vdd is given to the outer peripheral ring region 20. As a result, in the outer peripheral region 18, the potential difference of the power supply voltage Vdd is applied not only in the Z axis direction but also in the X axis direction.

To absorb the potential difference in the Z axis direction in the outer peripheral region 18 in an off state, a method for depleting the entire second pn region 39 is used, as in the cell region 16. To absorb the potential difference in the X axis direction in the outer peripheral region 18 in an off state, combination of the following two methods is used.

One of them is a method of extending the depletion layer in the third semiconductor layer 44B via the insulating layer 14 by utilizing the field plate electrode 54 and the field plate wire 28 being grounded in an off state.

The other one is a method of designing the n-type impurity concentration of the third column 39A and the p-type impurity concentration of the fourth column 39B in the second pn region 39 so as to deplete the entire second pn region 39 in an off state. Accordingly, the potential difference is absorbed using the X axis direction size of the second pn region 39.

When the third semiconductor layer 44B and the second pn region 39 are depleted by these two methods, the inclination of the potential is fixed in a direction from the second semiconductor layer 46 toward the outer peripheral ring region 20. When the X axis direction size of the second pn region 39 is d2, the electric field intensity is Vdd/d2 [V/cm]. It is desirable that at least the electric field is equal to lower than the avalanche breakdown electric field of the semiconductor.

However, in actuality, the balance of the impurity concentrations of the columns in the first pn region 38 and the second pn region 39 may be lost due to variations on manufacturing, whereby the electric field intensity can become locally high and the withstand voltage can be reduced. In particular, variation in the X axis direction widths of the fourth columns 39B can have an impact on the withstand voltage.

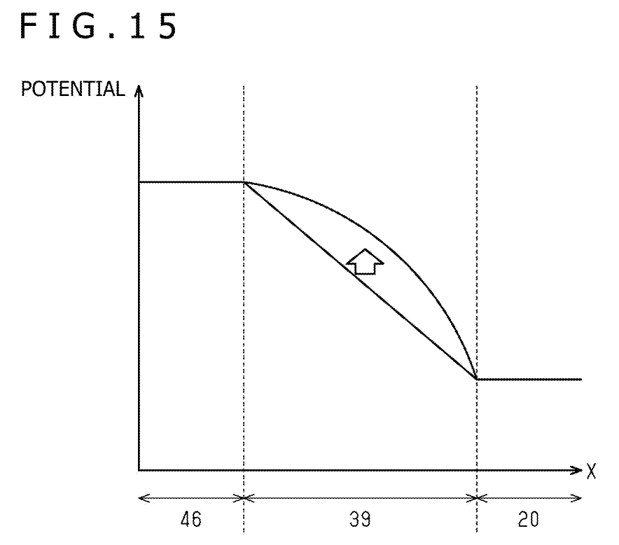

In a case where the X axis direction width of the fourth column 39B is increased, p-type impurities that are present in the entire fourth column 39B can be increased, so that the hole concentration of the fourth column 39B can be increased. As depicted in FIG. 15, as the hole concentration increases, the potential increases in a direction from the second semiconductor layer 46 toward the outer peripheral ring region 20. Before the X axis direction width of the fourth column 39B is increased, the inclination of the potential from the second semiconductor layer 46 toward the outer peripheral ring region 20 is fixed. However, if the X axis direction width of the fourth column 39B is increased, the potential increases. Due to this influence, the inclination of the potential in the second pn region 39 becomes a projecting arcuate inclination. As a result, since the inclination of the potential in the arcuate portion is small, the potential difference that cannot be absorbed in the second pn region 39 increases. Thus, there is a possibility that electric fields are concentrated around the boundary between the outer peripheral ring region 20 and the second pn region 39.

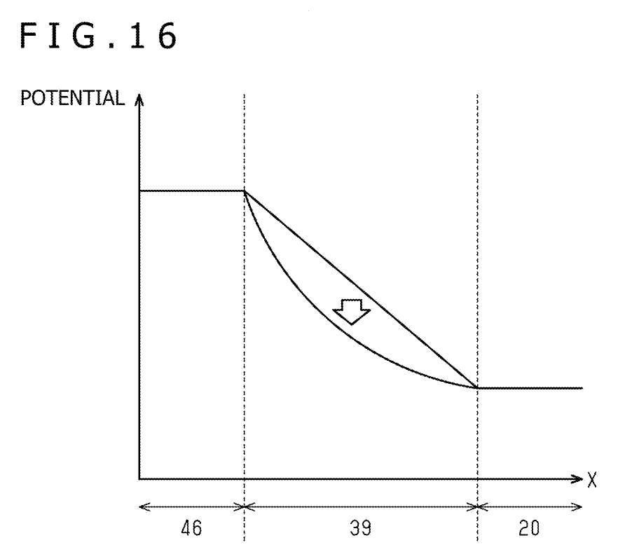

On the other hand, if the X axis direction width of the fourth column 39B is reduced, p-type impurities that are present in the entire fourth column 39B can be reduced, so that the concentration of electrons in the fourth column 39B can increase. As depicted in FIG. 16, as the electron concentration increases, the potential decreases in a direction from the second semiconductor layer 46 toward the outer peripheral ring region 20. Accordingly, if the X axis direction width of the fourth column 39B is reduced, the potential decreases. Due to this influence, the inclination of the potential in the second pn region 39 becomes a downwardly projecting arcuate inclination. As a result, the inclination of the potential in an area from the potential of the second semiconductor layer 46 to the downwardly projecting portion increases. Thus, there is a possibility that electric fields are concentrated around the boundary between the second pn region 39 and the second semiconductor layer 46.

In the present embodiment, in order to achieve a state rich in p-type impurities (p rich) on the upper surface side of the second pn region 39 and a state poor in p-type impurities (n rich) on the lower surface side, the p-type impurity concentrations of the first to eighth regions 30A to 30H are set to increase from the first region 30A toward the eighth region 30H as depicted in FIG. 7. Accordingly, even if the X axis direction width of the fourth column 39B is large, the lower side is changed from the n rich state to an np equilibrium state to achieve the balance. Thus, the depletion layer easily expands to maintain the withstand voltage.

However, if the X axis direction width of the fourth column 39B is large, the upper surface side of the fourth column 39B can become p richer, so that the withstand voltage can be lowered.

In this regard, in the present embodiment, the first connection layer 61 connecting the seventh regions 30G to each other is provided. If the first connection layer 61 is formed by, for example, connecting the eighth regions 30H, the eighth region 30H and the third semiconductor layer 44B have an overlapping region in the Z axis direction. Thus, the n-type semiconductor layer of the third semiconductor layer 44B can be canceled by the first connection layer 61 which is the p-type semiconductor layer. In this case, there is a possibility that the hole concentration increases, and the depletion layer extending in the Z axis direction from the field plate electrode 54 and the field plate wire 28 becomes difficult to extend.

In the present embodiment, the first connection layer 61 which is the p-type semiconductor layer is disposed in a position where the seventh regions 30G are connected to each other, and are at an appropriate distance from the third semiconductor layer 44B in the Z axis direction. Accordingly, the depletion layer extending in the Z axis direction from the field plate electrode 54 and the field plate wire 28 easily extends. Therefore, an increase in the hole concentration on the upper surface side of the fourth column 39B can be suppressed. As a result, an increase of the potential can be suppressed, so that electric field concentration can be relaxed. Accordingly, even a p rich region can be depleted. Consequently, the withstand voltage of the semiconductor device 10 can be improved.

### EFFECTS OF FIRST EMBODIMENT

The semiconductor device 10 of the first embodiment provides the following effects.

The semiconductor device 10 includes the n-type semiconductor substrate 40, the cell region 16 disposed on the semiconductor substrate 40 and having a cell disposed thereon, and the outer peripheral region 18 disposed on the semiconductor substrate 40 and surrounding the cell region 16. The semiconductor device 10 includes the n-type first semiconductor layer 44A disposed across both of the cell region 16 and the outer peripheral region 18 on the semiconductor substrate 40, the first pn region 38 disposed on the cell region 16, extending in the thickness direction of the semiconductor substrate 40, and formed of the n-type first column 38A and the p-type second column 38B that extend in the thickness direction and are alternately arranged in the first direction perpendicular to the thickness direction, the p-type second semiconductor layer 46 positioned on the first pn region 38, extending in the first direction, and connected to the second column 38B, the second pn region 39 disposed in the outer peripheral region 18 and formed of the n-type third column 39A and the p-type fourth column 39B that extend in the thickness direction and are alternately arranged in the first direction, the n-type third semiconductor layer 44B positioned on the second pn region 39, extending in the first direction, and connected to the third column 39A, and the insulating layer 14 positioned on the second semiconductor layer 46 and the third semiconductor layer 44B. In the second pn region 39, the plurality of the fourth columns 39B are arranged to be spaced from each other in the first direction, and the plurality of the fourth columns 39B have, as both ends in the thickness direction, the fourth upper ends 37H and the fourth lower ends 37A. In the second pn region 39, the p-type first connection layer 61 connecting the plurality of the fourth columns 39B in an area excluding the fourth upper ends 37H is disposed.

With this configuration, the first connection layer 61 can be disposed in an appropriate position to reduce the hole concentration between the second pn region 39 and the third semiconductor layer 44B. Thus, the electric field concentration can be relaxed. Consequently, the withstand voltage of the semiconductor device 10 can be improved.

The first connection layer 61 is disposed between the fourth lower end 37A and the fourth upper end 37H. The first connection layer 61 connects portions of the plurality of the fourth columns 39B at the same thickness position.

With this configuration, since the first connection layer 61 is disposed in an appropriate position between the fourth lower end 37A and the fourth upper end 37H, the hole concentration between the second pn region 39 and the third semiconductor layer 44B can be reduced. Thus, electric field concentration can be relaxed. Consequently, the withstand voltage of the semiconductor device 10 can be improved.

(1−3) The first connection layer 61 is disposed closer to the fourth upper end 37H than the fourth lower end 37A. With this configuration, since the first connection layer 61 is disposed in an appropriate position closer to the fourth upper end 37H than the fourth lower end 37A, the hole concentration between the second pn region 39 and the third semiconductor layer 44B can be reduced. Thus, electric field concentration can be relaxed. Consequently, the withstand voltage of the semiconductor device 10 can be improved.

(1−4) The fourth column 39B is formed of the plurality of regions 30 having different p-type impurity concentrations in the thickness direction. The p-type impurity concentrations of the plurality of regions 30 decrease from the fourth upper end 37H toward the fourth lower end 37A. The fourth upper end 37H is a region, among the plurality of regions 30, closest to the third semiconductor layer 44B.

With this configuration, a state rich in p-type impurities (p rich) can be achieved on the upper surface side of the second pn region 39, and a state poor in p-type impurities (n rich) can be achieved on the lower surface side. Accordingly, even if the X axis direction width of the fourth column 39B is large, the electric field concentration can be relaxed. Consequently, the withstand voltage of the semiconductor device 10 can be improved.

(1-5) The plurality of regions 30 have respective peak concentrations. The peak concentrations of the plurality of regions 30 decrease from the fourth upper end 37H toward the fourth lower end 37A.

With this configuration, a state rich in p-type impurities (p rich) can be achieved on the upper surface side of the second pn region 39, and a state poor in p-type impurities (n rich) can be achieved on the lower surface side. Accordingly, even if the X axis direction width of the fourth column 39B is large, the electric field concentration can be relaxed. Consequently, the withstand voltage of the semiconductor device 10 can be improved.

(1-6) The plurality of regions 30 is formed of eight regions 30A to 30H. The first connection layer 61 is disposed at a same thickness position as a region one level lower than the fourth upper end 37H in the thickness direction. The corresponding regions of the fourth column 39B are connected.

With this configuration, since the connection layer 60 is disposed at the same thickness position as a region one level lower than the fourth upper end 37H in the thickness direction, the hole concentration between the second pn region 39 and the third semiconductor layer 44B can be reduced. Thus, the electric field concentration can be relaxed. Consequently, the withstand voltage of the semiconductor device 10 can be improved. If the number of the plurality of regions 30 is increased, and if the column width, the column spacing, or the impurity concentration of the column is changed, the first connection layer 61 is disposed in a position to facilitate expansion of the depletion layer extending in the Z axis direction from the field plate electrode 54 and the field plate wire 28. Thus, an effect of reducing the hole concentration can be obtained.

### SECOND EMBODIMENT

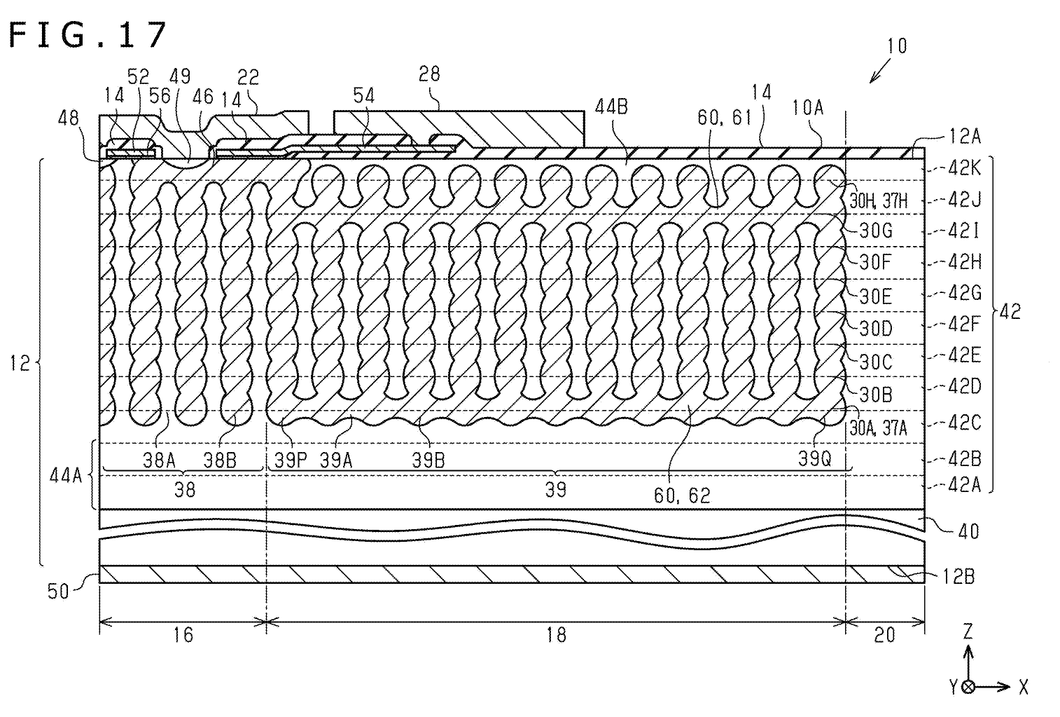

An entire schematic configuration of the semiconductor device 10 according to a second embodiment will be explained with reference to FIG. 17. The semiconductor device 10 of the second embodiment mainly differs from the semiconductor device 10 of the first embodiment in that, in the fourth columns 39B in the outer peripheral region 18, a second connection layer 62 connecting the first regions 30A to each other is provided in addition to the first connection layer 61 connecting the seventh regions 30G to each other. Elements the same as those of the first embodiment are denoted by the same reference signs, and an explanation thereof will be omitted.

### CONNECTION STRUCTURE OF FOURTH COLUMN

In the semiconductor device 10, in addition to the first connection layer 61, the second connection layer 62 connecting the plurality of the fourth columns 39B is further provided in the second pn region 39, as depicted in FIG. 17. That is, the connection layer 60 includes the first connection layer 61 and the second connection layer 62. The second connection layer 62 may be disposed below the first connection layer 61. In other words, the second connection layer 62 is disposed on the semiconductor substrate 40 side with respect to the first connection layer 61. In the present embodiment, the second connection layer 62 connects the plurality of fourth lower ends 37A. Here, the plurality of fourth lower ends 37A are portions, among the both ends of the fourth columns 39B, closest to the semiconductor substrate 40 in the Z axis direction. That is, it can be said that the second connection layer 62 connects the fourth lower ends 37A which are portions, of the plurality of the fourth columns 39B, closest to the semiconductor substrate 40 in the Z axis direction.

The p-type impurity concentration of the second connection layer 62 is equal to the p-type impurity concentration of the first region 30A.

In the present embodiment, since the p-type impurity concentrations of the first to eighth regions 30A to 30H are configured to decrease from the fourth upper end 37H toward the fourth lower end 37A, the p-type impurity concentration of the second connection layer 62 is lower than the p-type impurity concentration of the first connection layer 61. Alternatively, in a case where a connection layer is disposed, a concentration relation may freely be changed.

The second connection layer 62 is a p-type semiconductor layer. The second connection layer 62 is 1/4 of an annular region of a rounded rectangular region surrounding the outer edge 16A of the cell region 16 and including the outer edge 18A of the outer peripheral region 18 in plan view.

The second connection layer 62 is disposed in the same region as the first connection layer 61 in plan view. The second connection layer 62 and the first connection layer 61 overlap in plan view. The length of the first connection layer 61 is equal to the length of the second connection layer 62, when viewed in the X axis direction. The second connection layer 62 establishes connection from the innermost peripheral fourth column 39P to the outermost peripheral fourth column 39Q. The second connection layer 62 extends in a direction parallel with the upper surface 12A of the semiconductor device 10, and connects the adjacent fourth columns 39B to each other. In other words, the second connection layer 62 expands in the outer peripheral region 18 in an XY plan, and thereby covers the entire second pn region 39. The second connection layer 62 does not connect the second regions 30B to each other.

The plurality of the fourth columns 39B are electrically connected to the second semiconductor layer 46 via the innermost peripheral fourth column 39P extending from the bottom of the second semiconductor layer 46 having the p-type impurities as well toward the first semiconductor layer 44A in the Z axis direction and the first connection layer 61 and the second connection layer 62 connected to the innermost peripheral fourth column 39P.

Alternatively, the second connection layer 62 may be disposed in a region different from the first connection layer 61 in plan view. If the first connection layer 61 is disposed over an entire second pn region 29, the second connection layer 62 can be disposed to connect any fourth columns 39B. If the first connection layer 61 is not disposed over the second pn region 29, the second connection layer 62 can be disposed in such a way that the fourth column 39B to which the first connection layer 61 is not connected is electrically connected to the second semiconductor layer 46.

### OPERATION IN SECOND EMBODIMENT

Operation in the second embodiment will be explained using FIG. 17.

As described above, in order to achieve a state rich in p-type impurities (p rich) on the upper surface side of the second pn region 39 and a state poor in p-type impurities (n rich) on the lower side, the p-type impurity concentrations of the first to eighth regions 30A to 30H increase from the first region 30A toward the eighth region 30H. Accordingly, even if the X axis direction width of the fourth column 39B is large, the lower side is changed from the n rich state to an np equilibrium state to achieve the balance. Thus, the depletion layer expands to maintain the withstand voltage.

In addition, since the second connection layer 62 is disposed on the lower surface side of the second pn region 39, the lower surface of the second pn region 39 can be changed from a state poor in p-type impurities (n rich) to a state where the n-type and p-type impurity concentrations are well balanced. Accordingly, particularly if the X axis direction width of the fourth column 39B is small, a margin for ensuring the withstand voltage is increased. Accordingly, the withstand voltage of the semiconductor device 10 can be improved.

### EFFECTS OF SECOND EMBODIMENT

The semiconductor device 10 of the second embodiment described in detail so far provides the following effects in addition to those of the first embodiment.

(2-1) In addition to the first connection layer 61, the second connection layer 62 connecting the plurality of the fourth columns 39B is further disposed in the second pn region 39. The second connection layer 62 is disposed below the first connection layer 61. With this configuration, a state where the n-type and p-type impurity concentrations are well balanced can be achieved on the lower surface side of the second pn region 39. Consequently, the withstand voltage of the semiconductor device 10 can be improved.

(2-2) The second connection layer 62 connects the fourth lower ends 37A of the plurality of the fourth columns 39B. With this configuration, a state where the n-type and p-type impurity concentrations are well balanced can be achieved on the lower surface side of the second pn region 39. Consequently, the withstand voltage of the semiconductor device 10 can be improved.

### THIRD EMBODIMENT

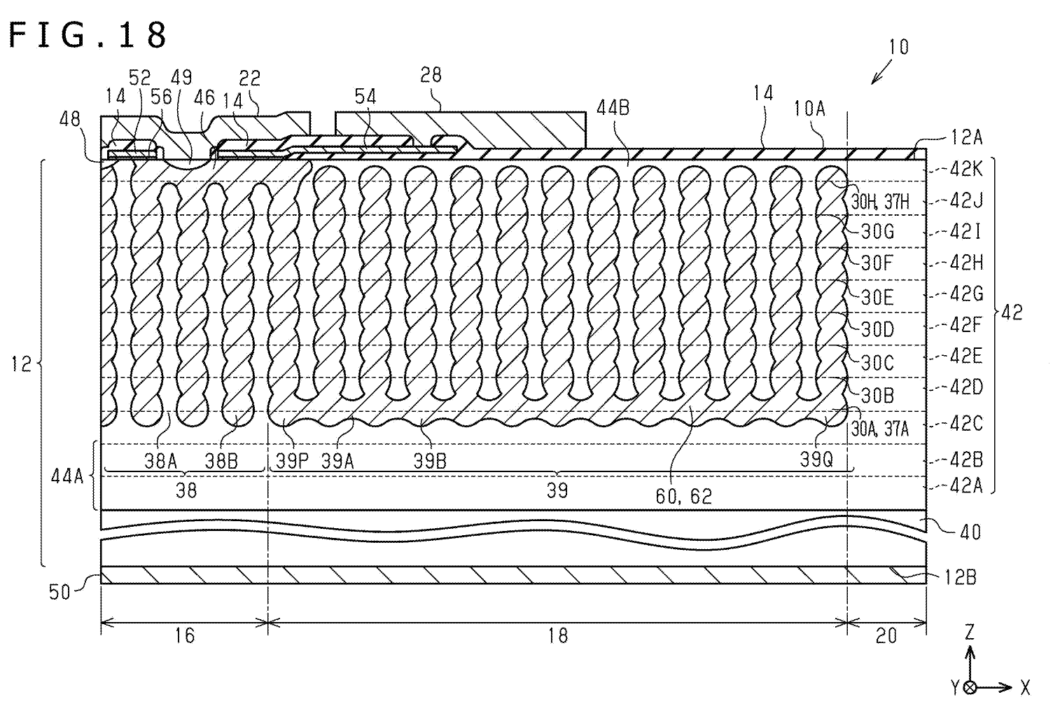

An entire schematic configuration of the semiconductor device 10 of a third embodiment will be explained with reference to FIG. 18. The semiconductor device 10 of the third embodiment mainly differs from the semiconductor device 10 according to the first embodiment in that, in the fourth columns 39B in the outer peripheral region 18, a second connection layer 62 connecting the first regions 30A to each other is provided in place of the first connection layer 61 connecting the seventh regions 30G to each other. Elements the same as those of the first embodiment are denoted by the same reference signs, and an explanation thereof will be omitted.

### PLANAR CONNECTION STRUCTURE OF FOURTH COLUMNS

The connection layer 60 includes the second connection layer 62, as depicted in FIG. 18. In the semiconductor device 10, the second connection layer 62 is disposed at the same thickness position as the fourth lower end 37A, and connects the fourth lower ends 37A to each other. The second connection layer 62 is a p-type semiconductor layer. The second connection layer 62 is 1/4 of an annular region of a rounded rectangular region surrounding the outer edge 16A of the cell region 16 and including the outer edge 18A of the outer peripheral region 18 in plan view. The second connection layer 62 is disposed in the same region as the first connection layer 61 (see FIG. 3) in plan view. The second connection layer 62 establishes connection from the innermost peripheral fourth column 39P to the outermost peripheral fourth column 39Q. The second connection layer 62 extends in a direction parallel with the upper surface 12A of the semiconductor layer 12, and connects the adjacent fourth columns 39B to each other. In other words, the second connection layer 62 expands in the outer peripheral region 18 in an XY plan, and thereby covers the entire second pn region 39.

The plurality of the fourth columns 39B are electrically connected to the second semiconductor layer 46 via the innermost peripheral fourth column 39P extending in the Z axis direction from the bottom of the second semiconductor layer 46 having the same p-type impurities toward the first semiconductor layer 44A and the second connection layer 62 connected to the innermost peripheral fourth column 39P.

### OPERATION AND EFFECTS OF THIRD EMBODIMENT

The semiconductor device 10 of the third embodiment described in detailed above provides the following operation and effects.

(3-1) The second connection layer 62 is disposed at the same thickness position as the fourth lower end 37A. The second connection layer 62 connects the fourth lower ends 37A to each other. With this configuration, a state where the n-type and p-type impurity concentrations are well balanced can be achieved on the lower surface side of the second pn region 39. Consequently, the withstand voltage of the semiconductor device 10 can be improved.

### MODIFICATIONS

The embodiments described above can be modified and implemented as follows. The embodiments and the following modifications can be combined with each other as long as any technical inconsistency does not arise.

In any of the first to third embodiments, when the X axis direction length of the fourth column 39B is the width of the fourth length, the width of the fourth upper end 37H may be larger than the width of the fourth lower end 37A. With this configuration, a p-type impurities rich state (p rich) can be achieved on the upper surface side of the second pn region 39, and a p-type impurities less state (n rich) can be achieved on the lower surface side. Consequently, the withstand voltage of the semiconductor device 10 can be improved.

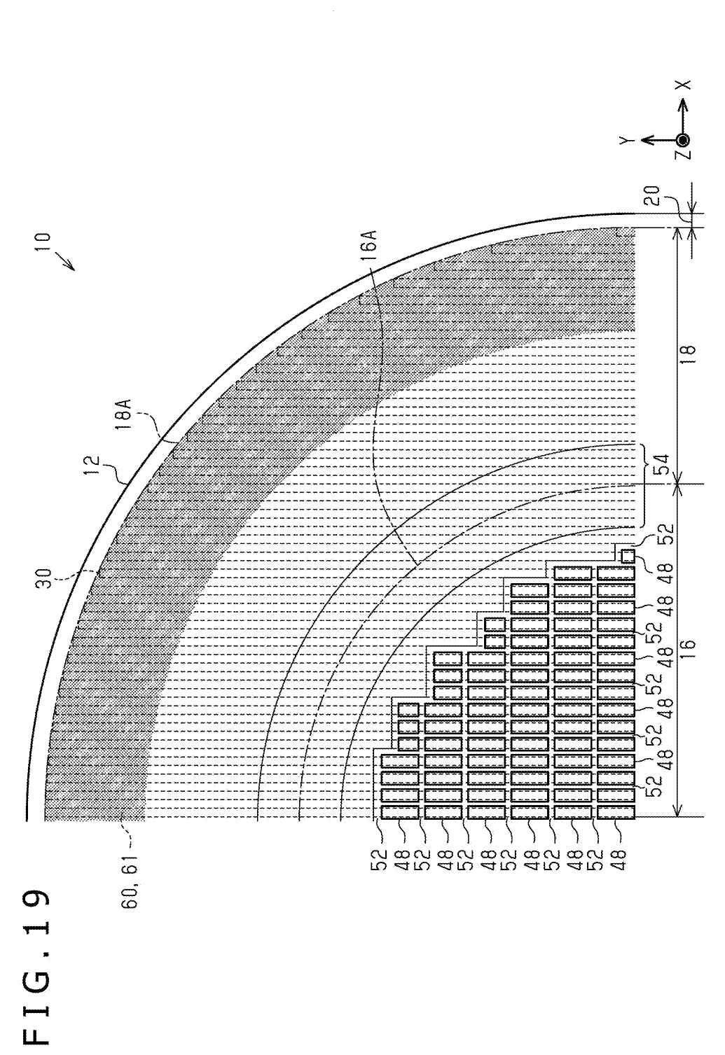

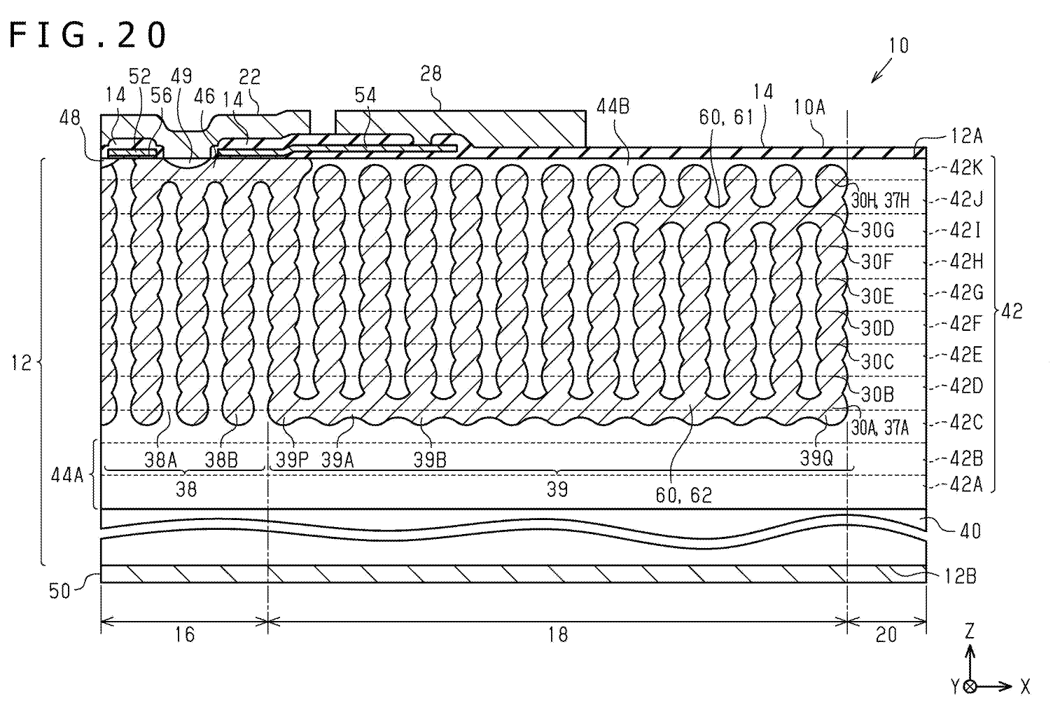

In any of the first to third embodiments, the connection layer 60 may be disposed closer to the outer edge 18A of the outer peripheral region 18 rather than the outer edge 16A of the cell region 16 in the outer peripheral region 18, as depicted in FIGS. 19 and 20. With this configuration, if a potential which is the potential of electrons as a carrier in the n-type MOSFET is low in the position of the second pn region 39 closer to the outer edge 18A of the outer peripheral region 18, the potential can be increased. Consequently, the withstand voltage of the semiconductor device 10 can be improved. In FIGS. 19 and 20, the first connection layer 61 is illustrated as the connection layer 60. However, the same modification can be made for the second connection layer 62.

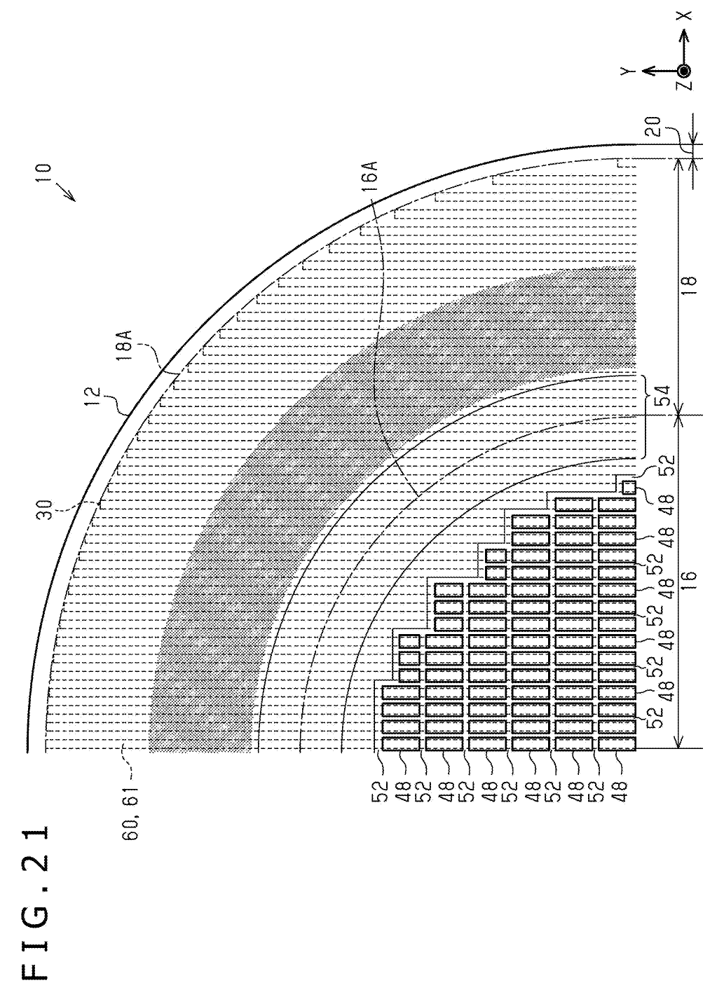

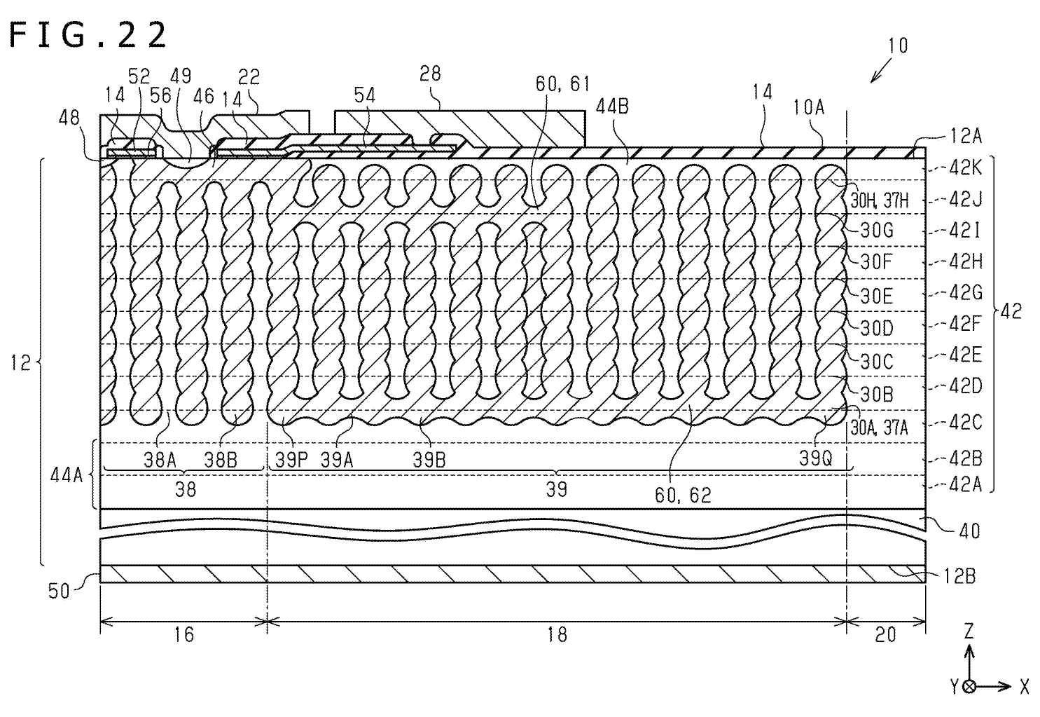

In the first to third embodiments, the connection layer 60 may be disposed at the side of the outer peripheral region 18 closer to the outer edge 16A of the cell region 16 than the outer edge 18A of the outer peripheral region 18 in plan view, as depicted in FIGS. 21 and 22. With this configuration, if the potential which is the potential of electrons which are a carrier in the n-type MOSFET is low in a position in the second pn region 39 close to the outer edge 16A of the cell region 16, the potential can be increased. Consequently, the withstand voltage of the semiconductor device 10 can be improved. In FIGS. 21 and 22, the first connection layer 61 is illustrated as the connection layer 60. However, the same modification can be made for the second connection layer 62.

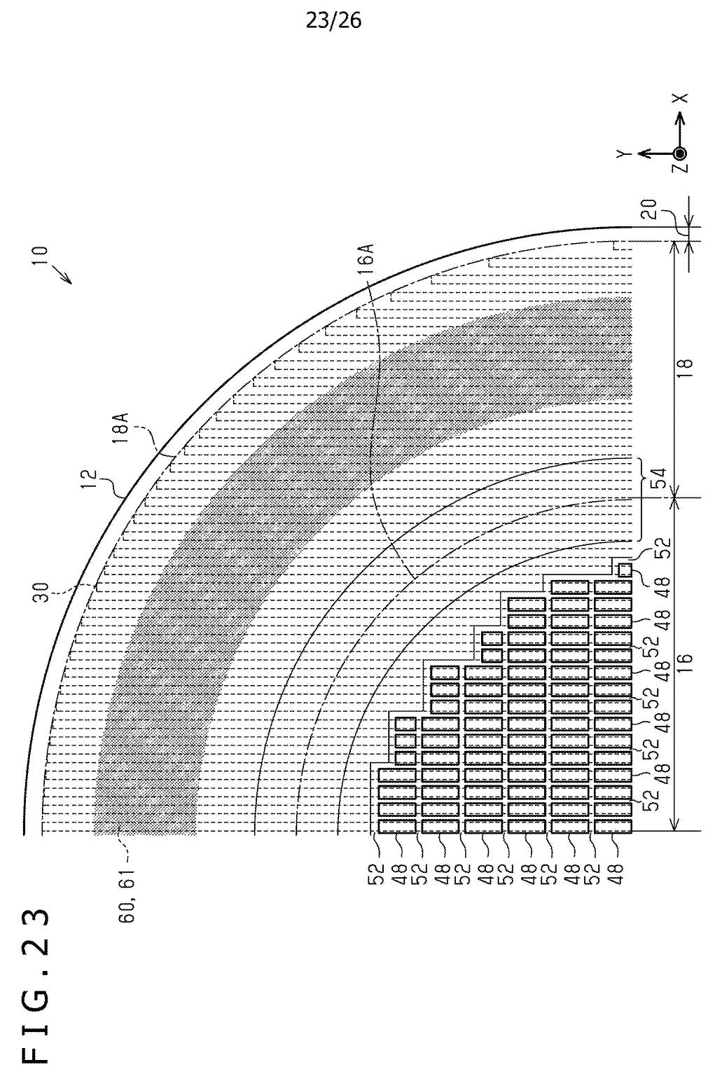

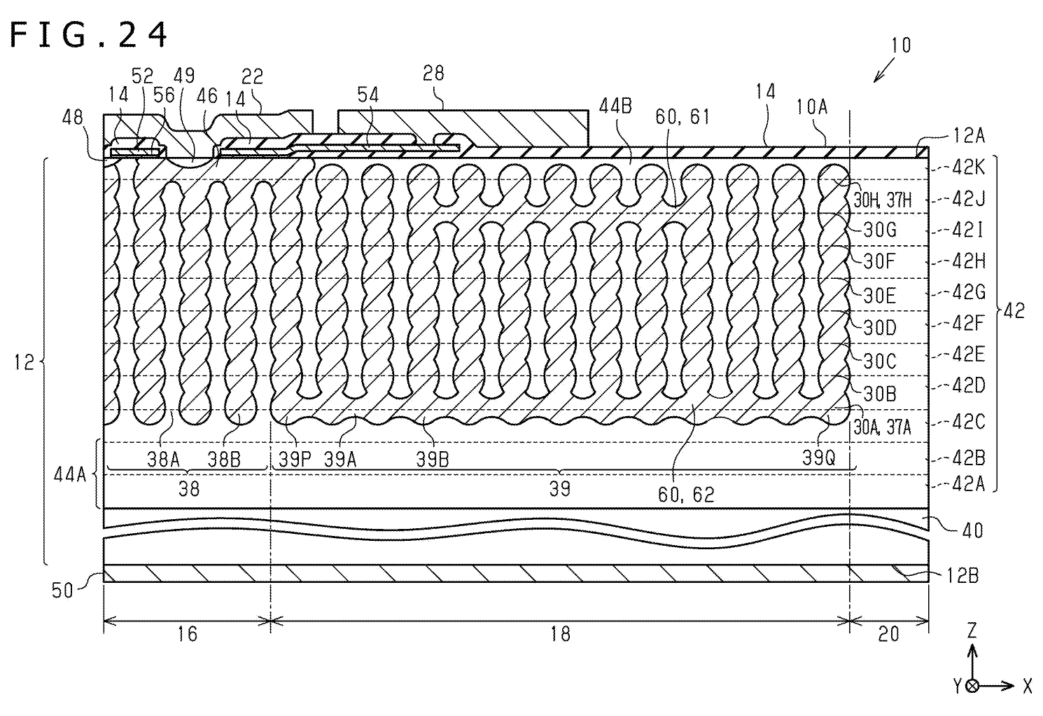

In the first to third embodiments, the connection layer 60 may be disposed between the outer edge 16A of the cell region 16 and the outer edge 18A of the outer peripheral region 18 and at a position spaced apart from both the outer edge 16A of the cell region 16 and the outer edge 18A of the outer peripheral region 18, as depicted in FIGS. 23 and 24. With this configuration, if a potential which is a potential of electrons as a carrier in the n-type MOSFET is low at a position, in the second pn region 39, spaced apart from both the outer edge 16A of the cell region 16 and the outer edge 18A of the outer peripheral region 18, the potential can be increased. Consequently, the withstand voltage of the semiconductor device 10 can be improved. In FIGS. 23 and 24, the first connection layer 61 is illustrated as the connection layer 60. However, the same modification can be made for the second connection layer 62.

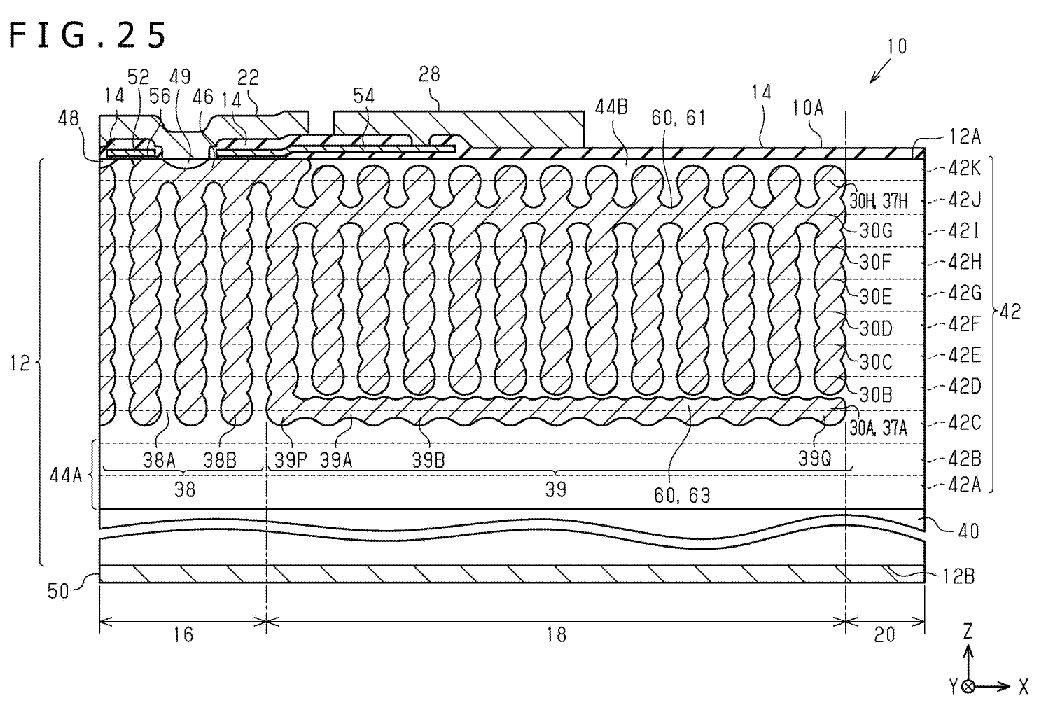

The first embodiment may include a second conductive type third connection layer 63 that is between the second pn region 39 and the semiconductor substrate 40 in the first semiconductor layer 44A and extends in the first direction, as depicted in FIG. 25. The third connection layer 63 is connected to the first region 30A which is the lower end of the innermost peripheral column 39P disposed adjacent to the outer edge 16A of the cell region 16. With this configuration, a state where n-type and p-type impurity concentrations are well balanced can be achieved on the lower surface side of the second pn region 39. Consequently, the withstand voltage of the semiconductor device 10 can be improved.

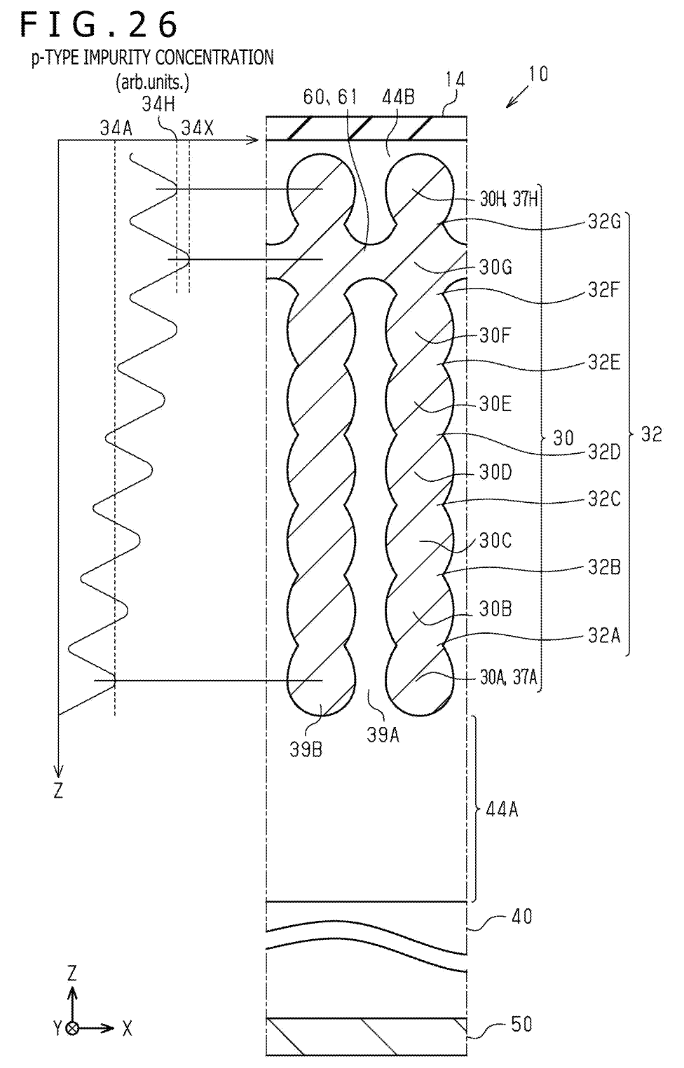

In the first to third embodiments, the fourth column 39B may be formed of a plurality of regions 30 having different second conductive type impurity concentrations in the Z axis direction, as depicted in FIG. 26. The second conductive type impurity concentrations of the plurality of regions 30 may include an upper end concentration included in the eighth region 30H, a lower end included in the first region 30A, and an intermediate portion concentration included between the eighth region 30H and the first region 30A. These concentrations are obtained by averaging the impurity concentrations in each region. The intermediate portion concentration may be higher than the lower end concentration, and the upper end concentration may be lower than the intermediate portion concentration. With this configuration, an effect of reducing the hole concentration between the second pn region 39 and the third semiconductor layer 44B can be enhanced. Thus, electric field concentration can be relaxed. Consequently, the withstand voltage of the semiconductor device 10 can be improved.

In the first to third embodiments, the fourth column 39B may have a second conductive type impurity concentration distribution including a plurality of peak concentrations in the Z axis direction, as depicted in FIG. 26. The plurality of peak concentrations may include an upper end peak concentration 34H included in the eighth region 30H, a lower end peak concentration 34A included in the first region 30A, and an intermediate portion peak concentration 34X included between the eighth region 30H and the first region 30A. The intermediate portion peak concentration 34X may be higher than the lower end peak concentration 34A, and the upper end peak concentration 34H may be lower than the intermediate portion peak concentration 34X. With this configuration, an effect of reducing the hole concentration between the second pn region 39 and the third semiconductor layer 44B can be enhanced. Thus, electric field concentration can be relaxed. Consequently, the withstand voltage of the semiconductor device 10 can be improved.

In the first to third embodiments, the connection layer 60 may be formed of a plurality of connection regions having different p-type impurity concentrations in the X axis direction. The second conductive type impurity concentrations of the plurality of connection regions may decrease from the outer edge 16A side of the cell region 16 toward the outer edge 18A side of the outer peripheral region 18. With this configuration, if the potential on the outer edge 18A side of the outer peripheral region 18 is high in the second pn region 39, the potential can be reduced. Consequently, the withstand voltage of the semiconductor device 10 can be improved.

In the first to third embodiments, the connection layer 60 may have a p-type impurity concentration distribution including a plurality of peak concentrations in the X axis direction. The plurality of peak concentrations may include an inner peak concentration included in the outer edge 16A side of the cell region 16, and an outer peak concentration included in the outer edge 18A side of the outer peripheral region 18. The inner peak concentration may be higher than the outer peak concentration. With this configuration, if the potential on the outer edge 18A side of the outer peripheral region 18 is low in the second pn region 39, the potential can be increased. Consequently, the withstand voltage of the semiconductor device 10 can be improved.

In the first to third embodiments, a second conductive type connection layer 60 connecting, in the fourth upper end 37H, the plurality of the fourth columns 39B may be disposed in the second pn region 39.

In the first to third embodiments, the first connection layer 61 does not need to connect the portions at the same thickness position.

In the first to third embodiments, the distance between the first connection layer 61 and the fourth lower end 37A in the Z axis direction may be shorter than the distance between the first connection layer 61 and the fourth upper end 37H in the Z axis direction.

In the first to third embodiments, the second conductive type impurity concentrations of the plurality of regions 30 may be fixed or may increase from the fourth upper end 37H to the fourth lower end 37A.

In the first to third embodiments, the first conductive type impurity concentrations of the plurality of regions 30 may be fixed or may decrease from the fourth upper end 37H toward the fourth lower end 37A.

In the first to third embodiments, the peak concentrations of the plurality of regions 30 may be fixed or may increase from the fourth upper end 37H toward the fourth lower end 37A.

In the second embodiment, the second connection layer 62 may be disposed above the first connection layer 61.

In the first to third embodiments, the n-type and the p-type may be replaced with each other. For example, a p-type epitaxial layer may be grown on the p-type semiconductor substrate, and an n-type column may be formed by ion-injection.

### APPENDIXES

The technical concepts that can be grasped from the present disclosure are given below. Reference signs used in the above embodiments are added to corresponding elements in the Appendixes to aid understanding without any intention to impose limitations to these elements. The reference signs are given as examples to aid understanding, and the elements set forth in the Appendixes are not limited to those elements denoted by the reference signs.

### APPENDIX 1

A semiconductor device (10) including:

a first conductive type semiconductor substrate (40);

a cell region (16) disposed on the semiconductor substrate (40) and having a cell disposed therein;

an outer peripheral region (18) disposed on the semiconductor substrate (40) and surrounding the cell region (16);

a first conductive type first semiconductor layer (44A) disposed across both the cell region (16) and the outer peripheral region (18) on the semiconductor substrate (40);

a first pn region (38) disposed in the cell region (16), extending in a thickness direction (Z) of the semiconductor substrate (40), and formed of a first conductive type first column (38A) and a second conductive type second column (38B) that are alternately disposed in a first direction (X) perpendicular to the thickness direction (Z);

a second conductive type second semiconductor layer (46) positioned on the first pn region (38), extending in the first direction (X), and connected to the second column (38B);

a second pn region (39) disposed in the outer peripheral region (18), extending in the thickness direction (Z), and formed of a first conductive type third column (39A) and a second conductive type fourth column (39B) that are alternately disposed in the first direction (X);

a first conductive type third semiconductor layer (44B) positioned on the second pn region (39), extending in the first direction (X), and connected to the third column (39A); and

an insulating layer (14) disposed on the second semiconductor layer (46) and the third semiconductor layer (44B), in which,

in the second pn region (39), a plurality of the fourth columns (39B) are arranged to be spaced from each other in the first direction (X),

the plurality of the fourth columns (39B) each have a fourth upper end (37H) and a fourth lower end (37A) as both ends in the thickness direction (Z), and

a second conductive type connection layer (60) connecting the plurality of the fourth columns (39B) in an area excluding the fourth upper end (37H) is disposed in the second pn region (39).

### APPENDIX 2

The semiconductor device (10) according to Appendix 1, in which

the connection layer (60) includes a first connection layer (61) disposed between the fourth lower end (37A) and the fourth upper end (37H) and connecting portions of the plurality of the fourth columns (39B) at a same thickness position.

### APPENDIX 3

The semiconductor device (10) according to Appendix 2, in which

the first connection layer (61) is disposed closer to the fourth upper end (37H) than the fourth lower end (37A).

### APPENDIX 4

The semiconductor device (10) according to any one of Appendixes 1 to 3, in which

the fourth column (39B) is formed of a plurality of regions (30) having different second conductive type impurity concentrations in the thickness direction (Z),

the second conductive type impurity concentrations of the plurality of regions (30) decrease from the fourth upper end (37H) toward the fourth lower end (37A), and

the fourth upper end (37H) is a region, among the plurality of regions (30), closest to the third semiconductor layer (44B).

### APPENDIX 5

The semiconductor device (10) according to Appendix 4, in which

the plurality of regions (30) respectively have peak concentrations, and

the peak concentrations of the plurality of regions (30) decrease from the fourth upper end (37H) toward the fourth lower end (37A).

### APPENDIX 6

The semiconductor device (10) according to Appendix 4 or 5, in which

the plurality of regions (30) is composed of eight regions (30A to 30H), and

the connection layer (60) is disposed in a same thickness position as a region (30G) under one level lower than a region of the fourth upper end (37H) in the thickness direction (Z), and connects corresponding regions (30G) to each other in the fourth columns (39B).

### APPENDIX 7

The semiconductor device (10) according to any one of Appendixes 2 to 6, in which,

in addition to the first connection layer (61), a second connection layer (62) connecting the plurality of the fourth columns (39B) is further disposed in the second pn region (39), and

the second connection layer (62) is disposed below the first connection layer (61).

### APPENDIX 8

The semiconductor device (10) according to Appendix 7, in which

the second connection layer (62) connects the fourth lower ends (37A) to each other of the plurality of the fourth columns (39B).

### APPENDIX 9

The semiconductor device (10) according to Appendix 1, in which

the connection layer (60) includes a second connection layer (62) disposed in a same thickness position as the fourth lower ends (37A) and connecting the fourth lower ends (37A).

### APPENDIX 10

The semiconductor device (10) according to any one of Appendixes 1 to 9, in which

the fourth column (39B) has a second conductive type impurity concentration distribution including a plurality of peak concentrations in the thickness direction (Z), and

the plurality of peak concentrations include

an upper end peak concentration (34H) included in the fourth upper end (37H), and

a lower end peak concentration (34A) included in the fourth lower end (37A), and

the upper end peak concentration (34H) is higher than the lower end peak concentration (34A).

### APPENDIX 11

The semiconductor device (10) according to any one of Appendixes 1 to 10, in which,

when a length of the fourth column (39B) in the first direction (X) is defined as a width of the fourth column (39B), a width (31W) of the fourth upper end (37H) is larger than a width (31W) of the fourth lower end (37A).

### APPENDIX 12

The semiconductor device (10) according to any one of Appendixes 1 to 11, in which

the connection layer (60) is disposed, in the outer peripheral region (18), to be closer to an outer edge (16A) of the cell region (16) than an outer edge (18A) of the outer peripheral region (18) in plan view.

### APPENDIX 13

The semiconductor device (10) according to any one of Appendixes 1 to 11, in which

the connection layer (60) is disposed, in the outer peripheral region (18), to be closer to an outer edge (18A) of an outer peripheral region (18) than the outer edge (16A) of the cell region (16) in plan view.

### APPENDIX 14

The semiconductor device (10) according to any one of Appendixes 1 to 11, in which

the connection layer (60) is disposed in a position between an outer edge (16A) of the cell region (16) and an outer edge (18A) of the outer peripheral region (18) and spaced apart from both the outer edge (16A) of the cell region (16) and the outer edge (18A) of the outer peripheral region (18) in plan view.

### APPENDIX 15

The semiconductor device (10) according to any one of Appendixes 1 to 14, in which

the cell includes

a gate electrode (52) facing the second semiconductor layer (46),

a gate insulating film (56) disposed in a position between the second semiconductor layer (46) and the gate electrode (52), and

a first conductive type source region (48) disposed on the second semiconductor layer (46) adjacent to the gate electrode (52), and,

in the outer peripheral region (18), a field plate electrode (54) electrically connected to the gate electrode (52) is disposed on an upper surface of the insulating layer (14).

### APPENDIX 16

The semiconductor device (10) according to any one of Appendixes 1 to 14, in which

the cell includes

a gate electrode (52) facing the second semiconductor layer (46),

a gate insulating film (56) disposed in a position between the second semiconductor layer (46) and the gate electrode (52), and

a first conductive type source region (48) disposed on the second semiconductor layer (46) adjacent to the gate electrode (52), and,

in the outer peripheral region (18), a field plate electrode (54) electrically connected to the source region (48) is disposed on an upper surface of the insulating layer (14).

### APPENDIX 17

The semiconductor device (10) according to any one of Appendixes 1 to 16, including:

a second conductive type third connection layer (63) disposed in an area between the second pn region (39) and the semiconductor substrate (40) in the first semiconductor layer (44A), the second conductive type third connection layer (63) extending in the first direction (X), in which

the third connection layer (63) is connected to the fourth lower end (37A) of the fourth column (39P) that is disposed adjacent to the outer edge (16A) of the cell region (16).

### APPENDIX 18

The semiconductor device (10) according to any one of Appendixes 1 to 17, in which

the fourth column (39B) is formed of the plurality of regions (30) having different second conductive type impurity concentrations in the thickness direction (Z),

the second conductive type impurity concentrations of the plurality of regions (30) include

an upper end concentration included in the upper end (30H),

a lower end concentration included in the lower end (30A), and

an intermediate portion concentration included between the upper end (30H) and the lower end (30A),

the intermediate portion concentration is higher than the lower end concentration, and

the upper end concentration is lower than the intermediate portion concentration.

### APPENDIX 19

The semiconductor device (10) according to any one of Appendixes 1 to 17, in which

the fourth column (39B) has a second conductive type impurity concentration distribution including a plurality of peak concentrations in the thickness direction (Z),

the plurality of peak concentrations include

an upper end peak concentration (34H) included in the upper end (30H),

a lower end peak concentration (34A) included in the lower end (30A), and

an intermediate portion peak concentration (34X) included between the upper end (30H) and the lower end (30A),

the intermediate portion peak concentration (34X) is higher than the lower end peak concentration (34A), and

the upper end peak concentration (34H) is lower than the intermediate portion peak concentration (34X).

### APPENDIX 20

The semiconductor device (10) according to any one of Appendixes 1 to 19, in which

the connection layer (60) is formed of a plurality of connection regions having different second conductive type impurity concentrations in the first direction (X), and

the second conductive type impurity concentrations of the plurality of connection regions decrease from the outer edge (16A) side of the cell region (16) to the outer edge (18A) side of the outer peripheral region (18).

### APPENDIX 21

The semiconductor device (10) according to any one of Appendixes 1 to 19, in which

the connection layer (60) has a second conductive type impurity concentration distribution including a plurality of peak concentrations in the first direction (X),

the plurality of peak concentrations include

an inner peak concentration included in the outer edge (16A) side of the cell region (16), and

an outer peak concentration included in the outer edge (18A) side of the outer peripheral region (18), and

the inner peak concentration is higher than the outer peak concentration.

The present disclosure contains subject matter related to that disclosed in Japanese Patent Application No. 2025-051742 filed in the Japan Patent Office on Mar. 26, 2025, the entire content of which is hereby incorporated by reference.

What is claimed is:

1. A semiconductor device comprising:
a first conductive type semiconductor substrate;
a cell region disposed on the semiconductor substrate and having a cell disposed therein;
an outer peripheral region disposed on the semiconductor substrate and surrounding the cell region;
a first conductive type first semiconductor layer disposed across both the cell region and the outer peripheral region on the semiconductor substrate;
a first pn region disposed in the cell region, extending in a thickness direction of the semiconductor substrate, and formed of a first conductive type first column and a second conductive type second column that are alternately disposed in a first direction perpendicular to the thickness direction;
a second conductive type second semiconductor layer positioned on the first pn region, extending in the first direction, and connected to the second column;
a second pn region disposed in the outer peripheral region, extending in the thickness direction, and formed of a first conductive type third column and a second conductive type fourth column that are alternately disposed in the first direction;
a first conductive type third semiconductor layer positioned on the second pn region, extending in the first direction, and connected to the third column; and
an insulating layer disposed on the second semiconductor layer and the third semiconductor layer, wherein,
in the second pn region, a plurality of the fourth columns are arranged to be spaced from each other in the first direction,
the plurality of the fourth columns each have a fourth upper end and a fourth lower end as both ends in the thickness direction, and
a second conductive type connection layer connecting the plurality of the fourth columns in an area excluding the fourth upper end is disposed in the second pn region.

2. The semiconductor device according to claim 1, wherein
the connection layer includes a first connection layer disposed between the fourth lower end and the fourth upper end and connecting portions of the plurality of the fourth columns at a same thickness position.

3. The semiconductor device according to claim 2, wherein
the first connection layer is disposed closer to the fourth upper end than the fourth lower end.

4. The semiconductor device according to claim 1, wherein
the fourth column is formed of a plurality of regions having different second conductive type impurity concentrations in the thickness direction,
the second conductive type impurity concentrations of the plurality of regions decrease from the fourth upper end toward the fourth lower end, and
the fourth upper end is a region, among the plurality of regions, closest to the third semiconductor layer.

5. The semiconductor device according to claim 4, wherein
the plurality of regions respectively have peak concentrations, and
the peak concentrations of the plurality of regions decrease from the fourth upper end toward the fourth lower end.

6. The semiconductor device according to claim 5, wherein
the plurality of regions is composed of eight regions, and
the connection layer is disposed a same thickness position as a region under one level lower than a region of the fourth upper end in the thickness direction, and connects corresponding regions to each other in the fourth columns.

7. The semiconductor device according to claim 2, wherein,
in addition to the first connection layer, a second connection layer connecting the plurality of the fourth columns is further disposed in the second pn region, and
the second connection layer is disposed below the first connection layer.

8. The semiconductor device according to claim 7, wherein
the second connection layer connects the fourth lower ends to each other of the plurality of the fourth columns.

9. The semiconductor device according to claim 1, wherein
the connection layer includes a second connection layer disposed in a same thickness position as the fourth lower ends and connecting the fourth lower ends.

10. The semiconductor device according to claim 1, wherein
the fourth column has a second conductive type impurity concentration distribution including a plurality of peak concentrations in the thickness direction, and
the plurality of peak concentrations include
an upper end peak concentration included in the fourth upper end, and
a lower end peak concentration included in the fourth lower end, and
the upper end peak concentration is higher than the lower end peak concentration.

11. The semiconductor device according to claim 1, wherein,
when a length of the fourth column in the first direction is defined as a width of the fourth column, a width of the fourth upper end is larger than a width of the fourth lower end.

12. The semiconductor device according to claim 1, wherein
the connection layer is disposed, in the outer peripheral region, to be closer to an outer edge of the cell region than an outer edge of the outer peripheral region in plan view.

13. The semiconductor device according to claim 1, wherein
the connection layer is disposed, in a outer peripheral region, to be closer to an outer edge of the outer peripheral region than an outer edge of the cell region in plan view.

14. The semiconductor device according to claim 1, wherein
the connection layer is disposed in a position between an outer edge of the cell region and an outer edge of the outer peripheral region and spaced apart from both the outer edge of the cell region and the outer edge of the outer peripheral region in plan view.

15. The semiconductor device according to claim 1, wherein
the cell includes
a gate electrode facing the second semiconductor layer,
a gate insulating film disposed in a position between the second semiconductor layer and the gate electrode, and
a first conductive type source region disposed on the second semiconductor layer adjacent to the gate electrode, and,
in the outer peripheral region, a field plate electrode electrically connected to the gate electrode is disposed on an upper surface of the insulating layer.

16. The semiconductor device according to claim 1, wherein
the cell includes
a gate electrode facing the second semiconductor layer,
a gate insulating film disposed in a position between the second semiconductor layer and the gate electrode, and
a first conductive type source region disposed on the second semiconductor layer adjacent to the gate electrode, and,
in the outer peripheral region, a field plate electrode electrically connected to the source region is disposed on an upper surface of the insulating layer.
